(19) United States
(12) Patent Application Publication
(10) Pub. No.: US 2026/0090228 A1
(43) Pub. Date: Mar. 26, 2026

(54) DISPLAY DEVICE

(71) Applicant: LG Display Co., Ltd., Seoul (KR)

(72) Inventors: SangBin LEE, Paju-si (KR); SungJin PARK, Paju-si (KR)

(73) Assignee: LG Display Co., Ltd., Seoul (KR)

(21) Appl. No.: 19/305,498

(22) Filed: Aug. 20, 2025

(30) Foreign Application Priority Data
Sep. 20, 2024 (KR) 10-2024-0127525

(51) Int. Cl. H10K 59/35; H10K 59/122

(52) U.S. Cl. CPC H10K 59/353; H10K 59/122; H10K 59/352

(57) ABSTRACT

A display device includes a substrate having a display area for image display. The display area includes a first display area having a plurality of light-emitting areas and at least one transmissive area, and a second display area positioned outside the first display area and including a plurality of light-emitting areas. An insulating layer is on the substrate with a plurality of pixel electrodes disposed on the insulating layer within the light-emitting areas of both display areas. An organic layer is on the pixel electrodes, and a common electrode is on the organic layer. The organic layer in both the first and second display areas include a plurality of organic patterns. In the first display area, the organic patterns include at least two organic patterns overlapping at least two pixel electrodes among the pixel electrodes, and at least two organic patterns that do not overlap with the at least two pixel electrodes.

### CROSS-REFERENCE TO RELATED APPLICATION

This application claims priority from Korean Patent Application No. 10-2024-0127525, filed on September 20, 2024, which is hereby incorporated by reference for all purposes as if fully set forth herein.

### BACKGROUND

### TECHNICAL FIELD

The present disclosure relates to a display device.

### DESCRIPTION OF THE RELATED ART

With technological advancements, display devices may provide not only image display functions but also additional features such as photography and various sensing capabilities. To achieve this, a display device must be equipped with an electronic device (also referred to as a light-receiving device or sensor) that receives light and performs a predetermined operation, such as a camera or a sensing sensor.

Since an optoelectronic device must receive light from the front of the display device, it needs to be positioned where it can effectively capture light. Accordingly, in conventional display devices, a camera (including a camera lens and an image sensor) and a sensing sensor were inevitably exposed on the front. As a result, the bezel of the display device became larger, or significant design constraints may arise.

### BRIEF SUMMARY

Various embodiments of the disclosed display device incorporate optoelectronic components, such as cameras and sensors, positioned beneath the display panel. This configuration allows for full-screen functionality without visible openings or bezels. The display is divided into a first area that supports both image display and light transmission for the operation of the underlying electronic components, and a second area that is optimized solely for image quality without the need for light transmission. The first area includes selectively patterned organic layers, transmissive regions, and specialized electrode arrangements, including patterned common electrodes and adjacent metal structures, to ensure effective light transmission while maintaining image resolution.

To enhance light transmission in areas aligned with the electronic components, the design employs adjustments in pixel density or pixel size. The structure supports consistent fabrication processes by enabling uniform patterning across regions with different functional requirements. It accommodates light across various wavelength ranges, including visible, infrared, and ultraviolet, and is compatible with multiple display technologies such as organic light emitting diodes, inorganic light emitting diodes, and quantum dot displays. This approach provides a reliable and scalable method for integrating under-panel cameras and sensors into display devices used in mobile and consumer electronics.

For example, various embodiments of this specification may provide a display device with a light-transmitting structure that allows an electronic device requiring light reception from the front to properly receive light (e.g., visible light, infrared light, or ultraviolet light) while remaining unexposed on its front side.

Various embodiments of this specification may provide a display device that enables process optimization by simplifying and enhancing the efficiency of the manufacturing process, even with structural differences between a transmissive area — where high transmittance is required — and a non-transmissive area —where low or no transmittance is acceptable — due to the presence or absence of a light-transmitting structure.

The embodiments of this specification may provide a display device with high light transmittance in a region overlapping with the electronic device requiring light reception.

The embodiments of this specification may provide a display device with high resolution in a region overlapping with the electronic device requiring light reception.

A display device according to the embodiments of this specification may comprise: a substrate including a display area in which images are displayed, wherein the display area comprises a first display area including a plurality of light-emitting areas and at least one transmissive area, and a second display area positioned outside the first display area and including a plurality of light-emitting areas; an insulating layer disposed on the substrate; a plurality of pixel electrodes disposed on the insulating layer and positioned in each of the plurality of light-emitting areas included in each of the first and second display areas; an organic layer disposed on the plurality of pixel electrodes; and a common electrode disposed on the organic layer.

According to the display device of the embodiments of this specification, the organic layer in the first and second display areas may comprise a plurality of organic patterns.

According to the display device of the embodiments of this specification, in the first display area, the plurality of organic patterns may comprise at least two organic patterns overlapping with at least two pixel electrodes positioned in the first display area among the plurality of pixel electrodes, and at least two organic patterns that do not overlap with the at least two pixel electrodes.

A display device according to the embodiments of this specification may comprise: a substrate including a display area in which images are displayed, wherein the display area comprises a first display area including a plurality of light-emitting areas and at least one transmissive area, and a second display area positioned outside the first display area and including a plurality of light-emitting areas; an insulating layer disposed on the substrate; a plurality of pixel electrodes disposed on the insulating layer and positioned in each of the plurality of light-emitting areas included in each of the first and second display areas; an intermediate layer disposed on the plurality of pixel electrodes; a common electrode disposed on the intermediate layer; a light-transmitting pattern disposed on the intermediate layer and positioned in the first display area; a first metal positioned adjacent to the left side of the light-transmitting pattern; a second metal positioned adjacent to the right side of the light-transmitting pattern; a third metal positioned adjacent to the upper side of the light-transmitting pattern; and a fourth metal positioned adjacent to the lower side of the light-transmitting pattern.

According to the display device of the embodiments of this specification, the common electrode may have at least two openings positioned in the first display area. Each of the at least two light-transmitting patterns may be positioned inside each of the at least two openings or may be positioned to overlap with each of the at least two openings.

According to the display device of the embodiments of this specification, the distance between the light-transmitting pattern and the first metal may correspond to the distance between the light-transmitting pattern and the second metal. Similarly, the distance between the light-transmitting pattern and the third metal may correspond to the distance between the light-transmitting pattern and the fourth metal.

According to the embodiments of this specification, a display device may be provided with a light-transmitting structure that allows an electronic device requiring light reception from the front to properly receive light, such as visible light, infrared light, or ultraviolet light, while remaining unexposed on its front side.

According to the embodiments of this specification, a display device may be provided that enables process optimization by simplifying and enhancing the efficiency of the manufacturing process. This may be achieved by uniformly patterning the organic layer for light-emitting devices into multiple organic patterns in both the transmissive area, where high transmittance is required, and the non-transmissive area, where low transmittance is acceptable or where no transmittance is required, despite structural differences due to the presence or absence of a light-transmitting structure.

According to the embodiments of this specification, a display device with high light transmittance in a region overlapping with an electronic device requiring light reception may be provided.

According to the embodiments of this specification, a display device may be provided that has high light transmittance in a region overlapping with an electronic device requiring light reception, thereby achieving high resolution.

### BRIEF DESCRIPTION OF THE SEVERAL VIEWS OF THE DRAWINGS

FIG. 1 illustrates a display device according to the embodiments of this specification.

FIG. 2 is a system configuration diagram of a display device according to the embodiments of this specification.

FIG. 3 illustrates a display panel according to the embodiments of this specification.

FIG. 4 illustrates the structure of a first display area and a second display area of a display panel according to the embodiments of this specification.

FIG. 5 is a cross-sectional view of a display panel according to the embodiments of this specification.

FIG. 6 is a plan view of the second display area of a display panel according to the embodiments of this specification.

FIG. 7 is a plan view of the first display area of a display panel according to the embodiments of this specification.

FIG. 8 illustrates pixel electrodes in FIG. 7.

FIG. 9 illustrates organic patterns in FIG. 7.

FIG. 10 illustrates a common electrode and light-transmitting patterns in FIG. 7.

FIG. 11 is an enlarged plan view of a portion of FIG. 7.

FIG. 12 and FIG. 13 are cross-sectional views taken along line A-B of FIG. 11.

FIG. 14 is a cross-sectional view taken along line C-D of FIG. 11.

FIG. 15 is a cross-sectional view taken along line E-F of FIG. 11.

FIG. 16 is a cross-sectional view taken along line G-H of FIG. 11.

FIG. 17 is a plan view of the first display area of a display panel according to the embodiments of this specification.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of this specification will be explained in detail with reference to the accompanying drawings.

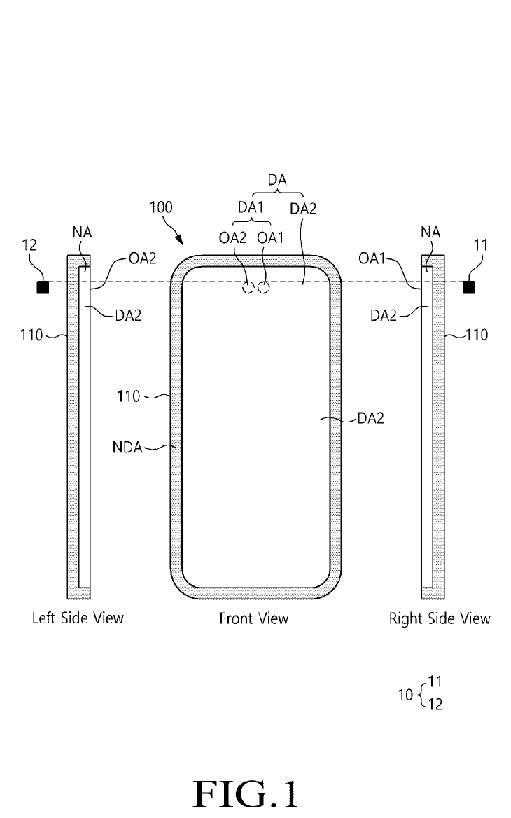

FIG. 1 illustrates a display device 100 according to the embodiments of this specification.

Referring to FIG. 1, the display device 100 according to the embodiments of this specification may comprise a display panel 110 that displays images and an electronic device 10.

The display panel 110 may comprise a display area DA, where images are displayed, and a non-display area NDA, where images are not displayed.

A plurality of sub-pixels may be arranged in the display area DA, and various signal lines for driving the plurality of sub-pixels may be disposed.

The non-display area NDA may be an outer region of the display area DA. Various signal lines may be disposed in the non-display area NDA, and various driving circuits may be connected. The non-display area NDA may be bent so as not to be visible from the front or may be covered by a case (not shown). The non-display area NDA is also referred to as a bezel or a bezel area.

In the display device 100 according to the embodiments of this specification, the electronic device 10 may be provided and installed separately from the display panel 110 and may be an electronic component positioned at the lower side (opposite to the viewing side) of the display panel 110.

In the display device 100 according to the embodiments of this specification, the electronic device 10 may be a device that receives light passing through the display panel 110 and performs a predetermined operation using the received light.

For example, the electronic device 10 may comprise at least one of an imaging device such as a camera (image sensor) and a sensing sensor such as a proximity sensor or an ambient light sensor. Here, for example, the sensing sensor may be an infrared sensor.

Light required for the operation of the electronic device 10 may enter through the front (viewing side) of the display panel 110, pass through the display panel 110, and be delivered to the electronic device 10 positioned below (opposite to the viewing side) the display panel 110. For example, the light required for the operation of the electronic device 10 and passing through the display panel 110 may comprise at least one of visible light, infrared light, or ultraviolet light.

In the display panel 110 according to the embodiments of this specification, the display area DA may comprise a first display area DA1 and a second display area DA2, which is different from the first display area DA1.

For example, the first display area DA1 may comprise at least one of a first optical area OA1 and a second optical area OA2. In this case, the electronic device 10 may comprise a first electronic device 11 overlapping with at least a portion of the first optical area OA1 and a second electronic device 12 overlapping with at least a portion of the second optical area OA2.

In one example, the first optical area OA1 and the second optical area OA2 may be separated from each other. In this case, the second display area DA2 may be present between the first optical area OA1 and the second optical area OA2.

In another example, the first optical area OA1 and the second optical area OA2 may not be separated but instead may be in contact with each other. In this case, the second display area DA2 is not present between the first optical area OA1 and the second optical area OA2. However, this is not limited thereto. For example, a third optical area may also be present at a location different from the first optical area OA1 and the second optical area OA2.

The first display area DA of the display panel 110 must have both an image display structure and a light-transmitting structure. That is, since the first display area DA of the display panel 110 is part of the display area DA, light-emitting areas of sub-pixels for image display must be arranged in the first display area DA. Additionally, the first display area DA of the display panel 110 must include a light-transmitting structure to allow light to pass through to the electronic device 10.

The electronic device 10 is positioned behind (below, opposite to the viewing side) the display panel 110 and receives light that has passed through the display panel 110.

The electronic device 10 is not exposed on the front (viewing side) of the display panel 110. Accordingly, when a user views the front of the display device 110, the electronic device 10 is not visible to the user.

For example, one of the first electronic device 11 and the second electronic device 12 may be a camera that receives light in the visible wavelength range (visible light), and the other may be a sensing sensor such as a proximity sensor or an ambient light sensor. For example, the sensing sensor may be an infrared sensor that detects light in the infrared wavelength range (infrared light). However, this is not limited thereto. For example, a third electronic device may be positioned in a third optical area that is spaced apart from the first optical area OA1 and the second optical area OA2. In this case, one of the first electronic device 11, the second electronic device 12, and the third electronic device may be a camera that receives light in the visible wavelength range (visible light), another may be an infrared sensing sensor that receives light in the infrared wavelength range (infrared light), and the remaining one may be a sensing sensor such as a proximity sensor or an ambient light sensor.

In one example, the first electronic device 11 may be a camera (image sensor), and the second electronic device 12 may be a sensing sensor. Alternatively, the first electronic device 11 may be a sensing sensor, and the second electronic device 12 may be a camera (image sensor).

Hereinafter, for ease of explanation, an example in which the first electronic device 11 is a camera, and the second electronic device 12 is an infrared-based sensing sensor will be described. Here, the camera may be a camera lens or an image sensor.

When the first electronic device 11 is a camera, the camera may be positioned behind (below) the display panel 110, but it may be a front camera that captures images in the front direction of the display panel 110. Accordingly, the user may take a photo (selfie capture) while looking at the viewing side of the display panel 110, using a camera that is not visible on the viewing side.

The second display area DA2 is an area that does not overlap with the electronic device 10 and is an area where a light-transmitting structure does not need to be formed, and may also be referred to as a general area.

The first display area DA1 and the second display area DA2, which are included in the display area DA, may have different light transmittance characteristics. The first display area DA1 must have a certain level of transmittance or higher, whereas the second display area DA2 may have no light transmittance or have low transmittance below a certain level.

Since the first display area DA1 and the second display area DA2, which are included in the display area DA, have different light transmittance characteristics, resolution, sub-pixel arrangement structure, the number of sub-pixels per unit area, electrode structure, line structure, electrode arrangement structure, or line arrangement structure, etc., may be different between the first display area DA1 and the second display area DA2.

For example, the first display area DA1 may have a relatively higher light transmittance than the second display area DA2.

In one example, to increase the transmittance of the first display area DA1, the first display area DA1 may have a lower resolution than the second display area DA2. For example, resolution may be defined by the number of sub-pixels per unit area, pixel density, or pixel pitch. Accordingly, the number of sub-pixels per unit area may have the same meaning as resolution, pixel density, or pixel pitch. For example, the unit of the number of sub-pixels per unit area may be PPI (Pixels Per Inch), which represents the number of pixels per inch.

The resolution of the first display area DA1 may be lower than the resolution of the second display area DA2. To achieve this, the number of sub-pixels per unit area in the first display area DA1 may be smaller than the number of sub-pixels per unit area in the second display area DA2.

In one example, as a method for increasing the transmittance of the first display area DA1, a pixel density differentiation design method may be applied. According to the pixel density differentiation design method, the display panel 110 may be designed such that the number of sub-pixels per unit area in the first display area DA1 is smaller than the number of sub-pixels per unit area in the second display area DA2. According to the pixel density differentiation design method, the resolution of the first display area DA1 may be lower than the resolution of the second display area DA2.

In another example, as another method for increasing the transmittance of the first display area DA1, a pixel size differentiation design method may be applied. According to the pixel size differentiation design method, the display panel 110 may be designed such that the number of sub-pixels per unit area in the first display area DA1 is the same as or similar to the number of sub-pixels per unit area in the second display area DA2, while the size of each sub-pixel SP (i.e., the size of the light-emitting area) arranged in the first display area DA1 is smaller than the size of each sub-pixel SP (i.e., the size of the light-emitting area) arranged in the second display area DA2. In one example, according to the pixel size differentiation design method, the resolution of the first display area DA1 may be the same as or similar to the resolution of the second display area DA2. In another example, according to the pixel size differentiation design method, the resolution of the first display area DA1 may be lower than the resolution of the second display area DA2.

To increase the transmittance of the first display area DA1, in addition to the aforementioned pixel density differentiation design method and pixel size differentiation design method, various other methods may also be applied.

In one example, the first optical area OA1 and the second optical area OA2 included in the first display area DA1 may have the same transmittance. In this case, the first optical area OA1 and the second optical area OA2 may have the same resolution.

In another example, the first optical area OA1 and the second optical area OA2 included in the first display area DA1 may have different transmittances. In this case, the first optical area OA1 and the second optical area OA2 may have different resolutions. In one example, the first optical area OA1 may have a relatively higher light transmittance and a lower resolution than the second optical area OA2. To achieve this, the number of sub-pixels per unit area in the first optical area OA1 may be equal to or smaller than the number of sub-pixels per unit area in the second optical area OA2. The number of sub-pixels per unit area in the second optical area OA2 may be smaller than the number of sub-pixels per unit area in the second display area DA2.

For example, the first optical area OA1 and the second optical area OA2 may have the same shape or different shapes. For example, the first optical area OA1 included in the first display area DA1 may have various shapes such as a circular, elliptical, rectangular, hexagonal, or octagonal shape. Similarly, the second optical area OA2 may have various shapes such as a circular, elliptical, rectangular, hexagonal, or octagonal shape.

For example, when the first optical area OA1 and the second optical area OA2 are in contact with each other, the first display area DA1, which includes the first optical area OA1 and the second optical area OA2, may have various shapes such as a circular, elliptical, rectangular, hexagonal, or octagonal shape. Hereinafter, for ease of explanation, the first optical area OA1 and the second optical area OA2 will be described as an example in which both have a circular shape.

In the display device 100 according to the embodiments of this specification, when the electronic device 10, which is hidden below the display panel 110 and not exposed externally, is a camera and/or a sensing sensor, the display device 100 may be referred to as a display to which UDC (Under Display Camera), UPC (Under Panel Camera), UDS (Under Display Sensor), or UPS (Under Panel Sensor) technology is applied.

Accordingly, in the display device 100 according to the embodiments of this specification, since a notch or a camera hole for exposing the camera does not need to be formed in the display panel 110, the area of the display area DA does not decrease. As a result, since a notch or a camera hole for exposing the camera does not need to be formed in the display panel 110, the size of the bezel area may be reduced, and design constraints may be eliminated, thereby increasing the degree of freedom in design.

In the display device 100 according to the embodiments of this specification, even though the electronic device 10 is positioned behind the display panel 110, the electronic device 10 must be capable of properly receiving light and performing a predetermined function normally.

Further, in the display device 100 according to the embodiments of this specification, even though the electronic device 10 is positioned behind the display panel 110 and overlaps with the display area DA, normal image display must be possible in the first display area DA1, which overlaps with the electronic device 10 within the display area DA.

Since the first display area DA1 mentioned above is designed as a transmissive area, the image display characteristics in the first display area DA1 may differ from those in the second display area DA2.

Additionally, when designing the first display area DA1, efforts to improve image display characteristics may lead to a decrease in transmittance.

Accordingly, the embodiments of this specification provide a structure of the first display area DA1 that can improve the transmittance of the first display area DA1 while preventing image quality deviation between the first display area DA1 and the second display area DA2.

Additionally, in the display device 100 according to the embodiments of this specification, although the first optical area OA1 and the second optical area OA2 included in the first display area DA1 are both light-transmitting areas, they may have different transmittances and resolutions due to their different applications. Accordingly, the structures of the first optical area OA1 and the second optical area OA2 may be fundamentally similar or identical, but differences may exist in resolution, sub-pixel arrangement structure, the number of sub-pixels per unit area, electrode structure, line structure, electrode arrangement structure, or line arrangement structure.

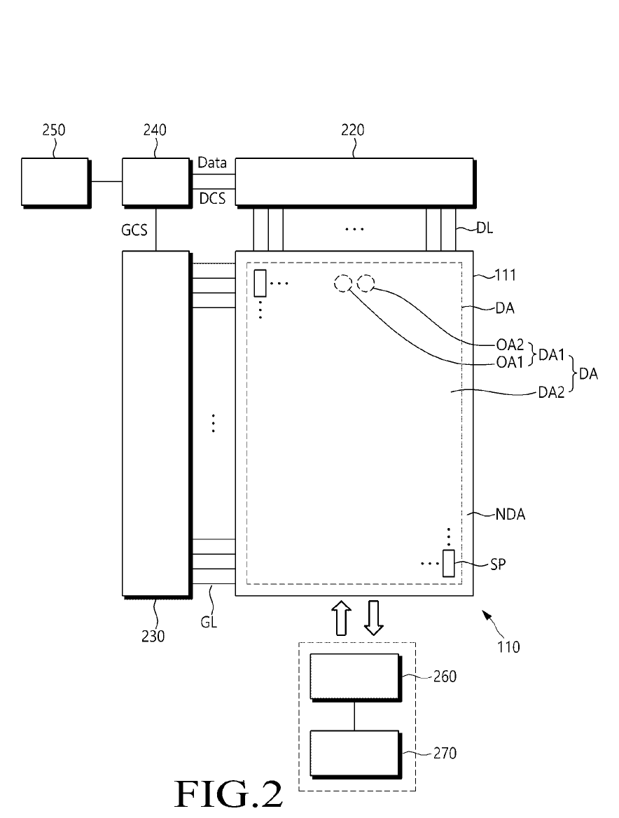

FIG. 2 is a system configuration diagram of the display device 100 according to the embodiments of this specification.

Referring to FIG. 2, the display device 100 may include, as components for image display, a display panel 110 and a display driving circuit. The display driving circuit may be a circuit for driving the display panel 110 and may include a data driving circuit 220, a gate driving circuit 230, and a display controller 240.

The display panel 110 may include a display area DA, in which images are displayed, and a non-display area NDA, in which images are not displayed. The non-display area NDA may be an outer region of the display area DA and may also be referred to as a bezel area. The entire or part of the non-display area NDA may be visible from the front of the display device 100 or may be bent so as not to be visible from the front of the display device 100.

The display panel 110 may include a substrate 111 and a plurality of sub-pixels SP disposed on the substrate 111. Additionally, the display panel 110 may further include various types of signal lines to drive the plurality of sub-pixels SP.

The display device 100 according to the embodiments of this specification may be a liquid crystal display or a self-emissive display in which the display panel 110 emits light by itself. When the display device 100 according to the embodiments of this specification is a self-emissive display, each of the plurality of sub-pixels SP may include a light-emitting device. For example, the display device 100 according to the embodiments of this specification may be an organic light-emitting display in which the light-emitting device is implemented as an organic light-emitting diode (OLED). In another example, the display device 100 according to the embodiments of this specification may be an inorganic light-emitting display in which the light-emitting device is implemented as an inorganic light-emitting diode. In yet another example, the display device 100 according to the embodiments of this specification may be a quantum dot display in which the light-emitting device is implemented as a quantum dot, which is a semiconductor crystal that emits light by itself.

Depending on the type of the display device 100, the structure of each of the plurality of sub-pixels SP may vary. For example, when the display device 100 is a self-emissive display in which each sub-pixel SP emits light by itself, each sub-pixel SP may include a light-emitting device which self-emits light, at least one transistor, and at least one capacitor.

For example, various types of signal lines may include a plurality of data lines DL, which transmit data signals (also referred to as data voltages or image signals), and a plurality of gate lines GL, which transmit gate signals (also referred to as scan signals).

The plurality of data lines DL and the plurality of gate lines GL may intersect with each other. Each of the plurality of data lines DL may be arranged extending in a first direction. Each of the plurality of gate lines GL may be arranged extending in a second direction. Here, the first direction may be a column direction, and the second direction may be a row direction. Alternatively, the first direction may be a row direction, and the second direction may be a column direction. Hereinafter, for ease of explanation, an example is provided in which each of the plurality of data lines DL is arranged in the column direction, and each of the plurality of gate lines GL is arranged in the row direction.

The data driving circuit 220 may be a circuit for driving the plurality of data lines DL and may output data signals to the plurality of data lines DL. The gate driving circuit 230 may be a circuit for driving the plurality of gate lines GL and may output gate signals to the plurality of gate lines GL.

The display controller 240 may be a device for controlling the data driving circuit 220 and the gate driving circuit 230 and may control the driving timing of the plurality of data lines DL and the driving timing of the plurality of gate lines GL.

The display controller 240 may supply a data driving control signal DCS to the data driving circuit 220 to control the data driving circuit 220 and may supply a gate driving control signal GCS to the gate driving circuit 230 to control the gate driving circuit 230.

The display controller 240 may receive input image data from a host system 250 and supply image data to the data driving circuit 220 based on the input image data.

The data driving circuit 220 may receive digital image data (Data) from the display controller 240, convert the received image data (Data) into analog data signals, and output the data signals to the plurality of data lines DL.

The gate driving circuit 230 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 220 may be connected to the display panel 110 using a tape automated bonding (TAB) method, connected to bonding pads of the display panel 110 using a chip-on-glass (COG) or chip-on-panel (COP) method, or implemented as a chip-on-film (COF) structure and connected to the display panel 110.

The gate driving circuit 230 may be connected to the display panel 110 using a tape automated bonding (TAB) method, connected to bonding pads of the display panel 110 using a chip-on-glass (COG) or chip-on-panel (COP) method, or connected to the display panel 110 using a chip-on-film (COF) method. Alternatively, the gate driving circuit 230 may be formed in the non-display area NDA of the display panel 110 as a gate-in-panel (GIP) type. The gate driving circuit 230 may be disposed on or connected to the substrate. That is, when the gate driving circuit 230 is of the GIP type, it may be disposed in the non-display area NDA of the substrate. When the gate driving circuit 230 is of the COG or COF type, it may be connected to the substrate.

Meanwhile, at least one of the data driving circuit 220 and the gate driving circuit 230 may be disposed in the display area DA of the display panel 110. For example, at least one of the data driving circuit 220 and the gate driving circuit 230 may be disposed such that it does not overlap with the sub-pixels SP, or it may be disposed such that it partially or entirely overlaps with the sub-pixels SP.

The data driving circuit 220 may be connected to one side (e.g., upper side or lower side) of the display panel 110. Depending on the driving method and panel design method, the data driving circuit 220 may be connected to both sides (e.g., upper side and lower side) of the display panel 110, or it may be connected to two or more of the four sides of the display panel 110.

The gate driving circuit 230 may be connected to one side (e.g., left side or right side) of the display panel 110. Depending on the driving method and panel design method, the gate driving circuit 230 may be connected to both sides (e.g., left side and right side) of the display panel 110, or it may be connected to two or more of the four sides of the display panel 110.

The display controller 240 may be implemented as a component separate from the data driving circuit 220, or it may be integrated with the data driving circuit 220 as an integrated circuit.

The display controller 240 may be a timing controller used in conventional display technology, a control device that includes a timing controller and performs additional control functions, a control device different from a timing controller, or a circuit within a control device. The display controller 240 may be implemented as various circuits or electronic components such as an IC (Integrated Circuit), FPGA (Field Programmable Gate Array), ASIC (Application Specific Integrated Circuit), or processor.

The display controller 240 may be mounted on a printed circuit board or a flexible printed circuit and electrically connected to the data driving circuit 220 and the gate driving circuit 230 through the printed circuit board or the flexible printed circuit, etc.

The display controller 240 may transmit and receive signals with the data driving circuit 220 according to at least one predefined interface. For example, the interface may include an LVDS (Low Voltage Differential Signaling) interface, an EPI (Embedded Clock Point-to-Point Interface) interface, an SPI (Serial Peripheral Interface), or the like.

The display device 100 according to the embodiments of this specification may further include a touch sensor and a touch sensing circuit that senses the touch sensor to detect whether a touch has occurred by a touch object such as a finger or a pen and to detect the touch position, in order to provide a touch sensing function in addition to an image display function.

The touch sensing circuit may include a touch driving circuit 260, which drives and senses the touch sensor to generate and output touch sensing data, and a touch controller 270, which detects a touch event or detects a touch position using the touch sensing data.

The touch sensor may include a plurality of touch electrodes. The touch sensor may further include a plurality of touch lines for electrically connecting the plurality of touch electrodes and the touch driving circuit 260.

The touch sensor may be present externally as a touch panel or internally within the display panel 110. When the touch sensor exists externally as a touch panel, it is referred to as an external-type touch sensor. When the touch sensor is an external-type touch sensor, the touch panel and the display panel 110 may be separately manufactured and then assembled during the assembly process. The external-type touch panel may include a substrate for the touch panel and a plurality of touch electrodes formed on the substrate for the touch panel.

When the touch sensor is present internally within the display panel 110, the touch sensor may be formed on the substrate 111 along with signal lines and electrodes related to display driving during the manufacturing process of the display panel 110.

The touch driving circuit 260 may supply a touch driving signal to at least one of the plurality of touch electrodes and sense at least one of the plurality of touch electrodes to generate touch sensing data.

The touch sensing circuit may perform touch sensing using a self-capacitance sensing method or a mutual-capacitance sensing method.

When the touch sensing circuit performs touch sensing using the self-capacitance sensing method, the touch sensing circuit may perform touch sensing based on the capacitance between each touch electrode and a touch object (e.g., a finger, a pen, etc.). According to the self-capacitance sensing method, each of the plurality of touch electrodes may function as both a driving touch electrode and a sensing touch electrode. The touch driving circuit 260 may drive and sense all or some of the plurality of touch electrodes.

When the touch sensing circuit performs touch sensing using the mutual-capacitance sensing method, the touch sensing circuit may perform touch sensing based on the capacitance between the touch electrodes. According to the mutual-capacitance sensing method, the plurality of touch electrodes are divided into driving touch electrodes and sensing touch electrodes. The touch driving circuit 260 may drive the driving touch electrodes and sense the sensing touch electrodes.

The touch driving circuit 260 and the touch controller 270 included in the touch sensing circuit may be implemented as separate devices or as a single device. Additionally, the touch driving circuit 260 and the data driving circuit 220 may be implemented as separate devices or as a single device.

The display device 100 may further include a power supply circuit that supplies various power sources to the display driving circuit and/or the touch sensing circuit.

The display device 100 according to the embodiments of this specification may be a mobile terminal such as a smartphone or a tablet, a monitor or television (TV) of various sizes, or any other type of display capable of presenting information or images, without being limited thereto.

As described above, the display area DA of the display panel 110 may include a first display area DA1 and a second display area DA2, which is different from the first display area DA1.

The first display area DA1 may be an area that overlaps with an electronic device 10, which receives light passing through the display panel 110 and performs a predetermined operation. The first display area DA1 may include a first optical area OA1 and a second optical area OA2. The first optical area OA1 may be an area overlapping with a first electronic device 11, and the second optical area OA2 may be an area overlapping with a second electronic device 12. The first display area DA1 may include at least one of the first optical area OA1 and the second optical area OA2 but is not limited thereto.

The first display area DA1 and the second display area DA2 may be areas where image display is possible. However, the second display area DA2 is an area where a light-transmitting structure does not need to be formed, whereas the first display area DA1 is an area where a light-transmitting structure must be formed.

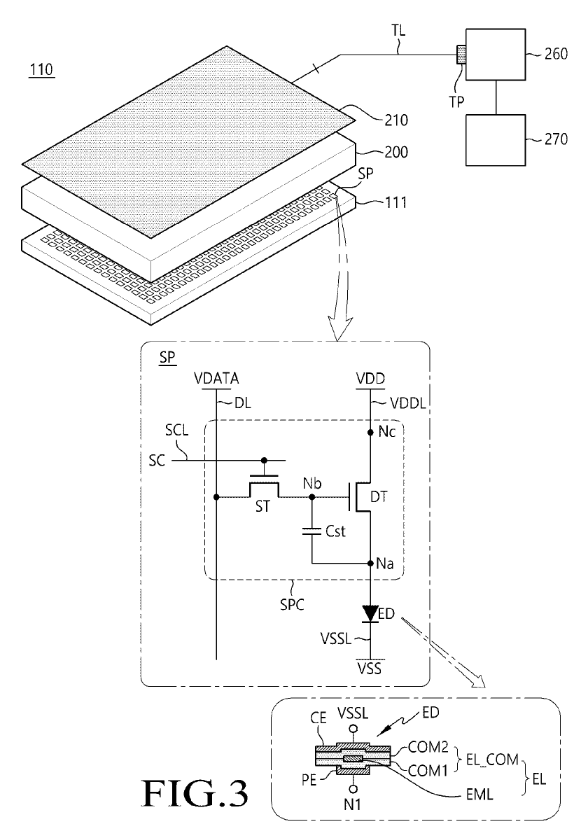

FIG. 3 illustrates a display panel 110 according to the embodiments of this specification.

Referring to FIG. 3, the display panel 110 according to the embodiments of this specification may include a substrate 111 on which a plurality of sub-pixels SP are disposed and an encapsulation layer 200 on the substrate 111. The encapsulation layer 200 may also be referred to as an encapsulation substrate or an encapsulation portion.

Referring to FIG. 3, when the display device 100 according to the embodiments of this specification is a self-emissive display, each of the plurality of sub-pixels SP disposed on the substrate 111 may include a light-emitting device ED and a sub-pixel circuit SPC for driving the light-emitting device ED.

Referring to FIG. 3, the sub-pixel circuit SPC may include a plurality of transistors and at least one capacitor for driving the light-emitting device ED, but embodiments of this specification are not limited thereto. In this specification, the sub-pixel circuit SPC may drive the light-emitting device ED by supplying a driving current to the light-emitting device ED at a predetermined timing. The light-emitting device ED may be driven by the driving current and emit light.

The plurality of transistors may include a driving transistor DT for driving the light-emitting device ED and a scan transistor ST that is turned on or off according to a scan signal SC.

The driving transistor DT may supply a driving current to the light-emitting device ED. The scan transistor ST may be configured to control the electrical state of a corresponding node in the sub-pixel circuit SPC or control the state or operation of the driving transistor DT. At least one capacitor may include a storage capacitor Cst for maintaining a constant voltage during a frame.

To drive the sub-pixel SP, a data signal VDATA, which is an image signal, and a scan signal SC, which is a type of gate signal, may be applied to the sub-pixel SP. Additionally, to drive the sub-pixel SP, common driving signals including a driving voltage VDD and a reference voltage VSS may be applied to the sub-pixel SP.

The light-emitting device ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each sub-pixel SP, and the common electrode CE may be an electrode commonly disposed in the plurality of sub-pixels SP. In one example, the pixel electrode PE may be an anode, and the common electrode CE may be a cathode. In another example, the pixel electrode PE may be a cathode, and the common electrode CE may be an anode. Hereinafter, for ease of explanation, an example is provided in which the pixel electrode PE is an anode and the common electrode CE is a cathode.

When the light-emitting device ED is an organic light-emitting device, the intermediate layer EL may include an emission layer EML, a first common intermediate layer COM1 disposed between the pixel electrode PE and the emission layer EML, and a second common intermediate layer COM2 disposed between the emission layer EML and the common electrode CE. The first common intermediate layer COM1 and the second common intermediate layer COM2 may be collectively referred to as a common intermediate layer EL_COM.

The emission layer EML may be disposed for each sub-pixel SP or may be commonly disposed across the plurality of sub-pixels SP. The common intermediate layer EL_COM may be commonly disposed across the plurality of sub-pixels SP, but the embodiments of this specification are not limited thereto.

That is, the emission layer EML may be disposed for each light-emitting area or may be commonly disposed across multiple light-emitting areas. The common intermediate layer EL_COM may be commonly disposed across the plurality of light-emitting areas and non-light-emitting areas, but the embodiments of this specification are not limited thereto.

For example, the first common intermediate layer COM1 may include a hole injection layer HIL, an electron blocking layer EBL, and a hole transport layer HTL, but the embodiments of this specification are not limited thereto. The second common intermediate layer COM2 may include an electron transport layer ETL, a hole blocking layer HBL, and an electron injection layer EIL, but the embodiments of this specification are not limited thereto.

The hole injection layer HIL may inject holes from the pixel electrode PE into the hole transport layer HTL, and the hole transport layer HTL may transport holes to the emission layer EML. The electron injection layer EIL may inject electrons from the common electrode CE into the electron transport layer ETL, and the electron transport layer ETL may transport electrons to the emission layer EML.

For example, the common electrode CE may be electrically connected to a reference voltage line VSSL. A reference voltage VSS, which is a type of common voltage, may be applied to the common electrode CE through the reference voltage line VSSL. The pixel electrode PE may be electrically connected directly or indirectly (via another transistor) to a first node Na of the driving transistor DT in each sub-pixel SP. In this specification, the reference voltage VSS may also be referred to as a first common voltage, a low-potential power supply voltage, or a low-potential voltage, and the reference voltage line VSSL may also be referred to as a first common voltage line, a low-potential power supply voltage line, or a low-potential voltage line.

Each light-emitting device ED may be formed by overlapping with the pixel electrode PE, the emission layer EML in the intermediate layer EL, and the common electrode CE. A predetermined light-emitting area may be defined by each light-emitting device ED. For example, the light-emitting area of each light-emitting device ED may include the overlapping area of the pixel electrode PE, the emission layer EML in the intermediate layer EL, and the common electrode CE.

For example, the light-emitting device ED may be an organic light-emitting diode (OLED), an inorganic light-emitting diode (LED), a quantum dot light-emitting device, a micro-LED, or a mini-LED, but the embodiments of this specification are not limited thereto. For example, when the light-emitting device ED is an organic light-emitting diode (OLED), the intermediate layer EL of the light-emitting device ED may include an organic material-containing intermediate layer EL.

The driving transistor DT may supply a driving current to the light-emitting device ED. The driving transistor DT may be connected between the driving voltage line VDDL and the light-emitting device ED.

The driving transistor DT may include a first node Na, a second node Nb, and a third node Nc. The first node Na may be electrically connected to the light-emitting device ED, the second node Nb may be a node to which the data signal VDATA is applied, and the third node Nc may be a node to which the driving voltage VDD, which is another type of common voltage, is applied from the driving voltage line VDDL. The driving transistor DT may be connected between the first node Na and the third node Nc. In this specification, the driving voltage VDD may also be referred to as a second common voltage, a high-potential power supply voltage, or a high-potential voltage, and the driving voltage line VDDL may also be referred to as a second common voltage line, a high-potential power supply voltage line, or a high-potential voltage line.

In the driving transistor DT, the second node Nb may be a gate node, the first node Na may be a source node or a drain node, and the third node Nc may be a drain node or a source node. Hereinafter, for ease of explanation, an example is provided in which, in the driving transistor DT, the second node Nb is a gate node, the first node Na is a source node, and the third node Nc is a drain node, but the embodiments of this specification are not limited thereto.

The scan transistor ST included in the sub-pixel circuit SPC illustrated in FIG. 3 may be a switching transistor for transmitting the data signal VDATA, which is an image signal, to the second node Nb, which is the gate node of the driving transistor DT.

The scan transistor ST may be controlled to turn on and off by a scan signal SC, which is a type of gate signal applied through a scan line SCL, which is a type of gate line GL, and may control the electrical connection between the second node Nb of the driving transistor DT and the data line DL. The drain electrode or source electrode of the scan transistor ST may be electrically connected to the data line DL, the source electrode or drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and the second node Nb of the driving transistor DT. The storage capacitor Cst may include at least one capacitor electrode that is electrically connected to or corresponding to the first node Na of the driving transistor DT, or at least one capacitor electrode that is electrically connected to or corresponding to the second node Nb of the driving transistor DT.

The storage capacitor Cst is not a parasitic capacitor (e.g., Cgs, Cgd), which is an internal capacitor that may exist between the first node Na and the second node Nb of the driving transistor DT, but rather an external capacitor that is intentionally designed outside the driving transistor DT. However, the embodiments of this specification are not limited thereto.

Each of the driving transistor DT and the scan transistor ST may be an n-type transistor or a p-type transistor, but the embodiments of this specification are not limited thereto. For example, one of the driving transistor DT and the scan transistor ST may be either an n-type transistor or a p-type transistor.

The display panel 110 may have a top-emission structure or a bottom-emission structure. When the display panel 110 has a top-emission structure, at least a portion of the sub-pixel circuit SPC may overlap with at least a portion of the light-emitting device ED in a vertical direction. Accordingly, the area of the light-emitting area may increase, and the aperture ratio may be improved. When the display panel 110 has a bottom-emission structure, the sub-pixel circuit SPC may not overlap with the light-emitting device ED in the vertical direction.

As illustrated in FIG. 3, the sub-pixel circuit SPC may have a 2T1C structure including two transistors (DT, ST) and one capacitor Cst. Depending on the case, the sub-pixel circuit SPC may further include one or more additional transistors or one or more additional capacitors.

In one example, the sub-pixel circuit SPC may have a 3T1C structure including three transistors and one capacitor. In another example, the sub-pixel circuit SPC may have an 8T1C structure including eight transistors and one capacitor. In yet another example, the sub-pixel circuit SPC may have a 6T2C structure including six transistors and two capacitors. In still another example, the sub-pixel circuit SPC may have a 7T1C structure including seven transistors and one capacitor. The embodiments of this specification are not limited thereto.

Depending on the structure of the sub-pixel circuit SPC, the type and number of gate lines supplying a gate signal to the sub-pixel SP may vary. Additionally, depending on the structure of the sub-pixel circuit SPC, the type and number of common driving signals supplied to the sub-pixel SP may vary.

Since circuit components within each sub-pixel SP (e.g., a light-emitting device ED implemented as an organic light-emitting diode (OLED) containing an organic material) are vulnerable to external moisture and oxygen, an encapsulation layer 200 may be disposed in the display panel 110. The encapsulation layer 200 may prevent external moisture and oxygen from penetrating into the circuit components (e.g., the light-emitting device ED). The encapsulation layer 200 may be configured in various forms to prevent the light-emitting devices ED from coming into contact with moisture or oxygen. For example, the encapsulation layer 200 may be formed of two or more layers in which an organic film and an inorganic film are alternately stacked. However, the embodiments of this specification are not limited thereto.

Referring to FIG. 3, the display device 100 according to the embodiments of this specification may include a touch sensor layer 210, in which a touch sensor is formed, and a touch sensing circuit that senses the touch sensor formed in the touch sensor layer 210 to determine whether a touch has occurred or to detect touch coordinates, in order to provide a touch sensing function.

For example, the touch sensing circuit may include a touch driving circuit 260 configured to drive and sense the touch sensor formed in the touch sensor layer 210 to generate and output touch sensing data, and a touch controller 270 configured to determine whether a touch has occurred or detect touch coordinates using the touch sensing data provided by the touch driving circuit 260.

The touch sensor layer 210 is a layer in which a touch sensor is formed, and the touch sensor may be composed of a plurality of touch electrodes.

In one example, the touch sensor layer 210 may be disposed outside the display panel 110 and may be configured as a separate touch panel distinct from the display panel 110. In this case, the touch panel and the display panel 110 may be separately manufactured and then assembled during the assembly process.

In another example, the touch sensor layer 210 may be embedded in the display panel 110. When the touch sensor layer 210 is included inside the display panel 110, the touch sensor layer 210 may be formed on the substrate 111 along with signal lines and electrodes related to display driving during the manufacturing process of the display panel 110. For example, the touch sensor layer 210 may be disposed on the encapsulation layer 200. Hereinafter, for ease of explanation, an example in which the touch sensor layer 210 is embedded in the display panel 110 will be described.

When the touch sensor layer 210 is embedded in the display panel 110, the display panel 110 may further include, in addition to the plurality of touch electrodes corresponding to the touch sensor, a plurality of touch pads TP electrically connected to the touch driving circuit 260 and a plurality of touch routing lines TL that electrically connect the plurality of touch electrodes and the plurality of touch pads TP. Here, the plurality of touch routing lines TL may also be referred to as a plurality of touch lines. Additionally, the plurality of touch routing lines TL may correspond to a plurality of touch channels.

The touch driving circuit 260 may supply a touch driving signal to at least one of the plurality of touch electrodes and may sense at least one of the plurality of touch electrodes to generate touch sensing data.

The touch sensing circuit may perform touch sensing using a self-capacitance sensing method or a mutual-capacitance sensing method.

When the touch sensing circuit performs touch sensing using the self-capacitance sensing method, it may perform touch sensing based on the capacitance between each touch electrode and a touch object (e.g., a finger or a pen). According to the self-capacitance sensing method, each of the plurality of touch electrodes may function as both a driving touch electrode and a sensing touch electrode. The touch driving circuit may drive all or some of the plurality of touch electrodes and may sense all or some of the plurality of touch electrodes.

When the touch sensing circuit performs touch sensing using the mutual-capacitance sensing method, it may perform touch sensing based on the capacitance between adjacent touch electrodes. According to the mutual-capacitance sensing method, the plurality of touch electrodes are divided into driving touch electrodes and sensing touch electrodes. The touch driving circuit may drive the driving touch electrodes and sense the sensing touch electrodes. The touch routing line connected to the driving touch electrodes may be referred to as driving touch routing line, and the touch routing line connected to the sensing touch electrodes may be referred to as sensing touch routing line.

The touch driving circuit 260 and the touch controller 270 may be implemented as separate devices or as a single device. Additionally, the touch driving circuit 260 and the data driving circuit 120 may be implemented as separate devices or as a single device.

The display device 100 may further include a power supply circuit that supplies various power sources to the display driving circuit and/or the touch sensing circuit. The power supply circuit may supply various voltages and power supply voltages related to display driving to the display driving circuit or the display panel 110.

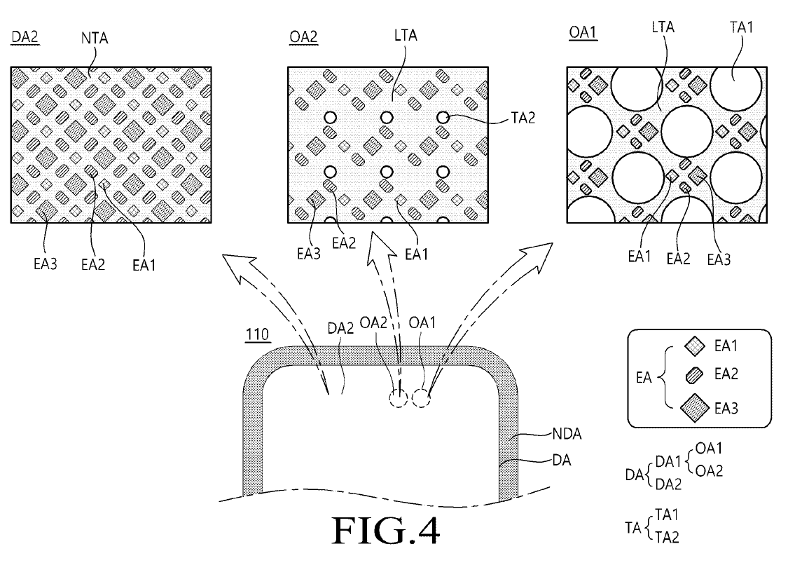

FIG. 4 illustrates the structure of the first display area DA1 and the second display area DA2 in the display panel 110 according to the embodiments of this specification.

Referring to FIG. 4, the display panel 110 according to the embodiments of this specification may include a display area DA in which images are displayed and a non-display area NDA in which images are not displayed. The display area DA may include a first display area DA1 and a second display area DA2. The first display area DA1 may include at least one of a first optical area OA1 and a second optical area OA2. In one example, the first display area DA1 may include both the first optical area OA1 and the second optical area OA2. In FIG. 4, an example is illustrated in which the first display area DA1 includes both the first optical area OA1 and the second optical area OA2.

Since the first display area DA1 and the second display area DA2 are included in the display area DA, they may have a display structure. For example, each of the first optical area OA1, the second optical area OA2, and the second display area DA2 may include a plurality of light-emitting areas EA.

Additionally, the first optical area OA1 and the second optical area OA2 may be areas where light transmission is possible, whereas the second display area DA2 may be an area where light transmission is impossible or minimal. The second display area DA2 may be an area where light cannot pass through or where light transmission is negligible and may refer to the area excluding the first display area DA1. Here, “light transmission” may mean that light entering the front of the display panel 110 passes through the display panel 110 and exits from the rear of the display panel 110.

The first optical area OA1 may be an area that overlaps with the first electronic device 11. The second optical area OA2 may be an area that overlaps with the second electronic device 12.

Each of the first optical area OA1 and the second optical area OA2 may have a light-transmitting structure. However, the first optical area OA1 and the second optical area OA2 may have different structural characteristics. For example, the light transmittance of the first optical area OA1 may be higher than that of the second optical area OA2. In another example, the resolution of the first optical area OA1 may be lower than that of the second optical area OA2. In yet another example, the number of sub-pixels per unit area in the first optical area OA1 may be smaller than that in the second optical area OA2. In still another example, the size of the sub-pixels in the first optical area OA1 may be smaller than that in the second optical area OA2.

The first electronic device 11 may perform a predetermined operation using light in a first wavelength band among the light transmitted through the first optical area OA1. The second electronic device 12 may perform a predetermined operation using light in a second wavelength band, different from the first wavelength band, among the light transmitted through the second optical area OA2.

The first wavelength band may include at least one of the wavelength bands of visible light, infrared light, and ultraviolet light. The second wavelength band may also include at least one of the wavelength bands of visible light, infrared light, and ultraviolet light but may be different from the first wavelength band.

For example, the first electronic device 11 may be a camera, and the second electronic device 12 may be a sensing sensor. The first electronic device 11 may perform a camera operation using light in a visible light wavelength band corresponding to the first wavelength band among the light transmitted through the first optical area OA1. The second electronic device 12 may perform a sensing operation using light in an infrared light wavelength band corresponding to the second wavelength band among the light transmitted through the second optical area OA2.

Referring to FIG. 4, each of the first optical area OA1 and the second optical area OA2 may have a circular or octagonal shape. However, the first optical area OA1 and the second optical area OA2 are not limited thereto and may have various shapes, such as elliptical, polygonal, or irregular shapes.

The first optical area OA1 and the second optical area OA2 may have the same shape. Alternatively, the first optical area OA1 and the second optical area OA2 may have different shapes.

Referring to FIG. 4, the display area DA may include a plurality of light-emitting areas EA. Since the first display area DA1 and the second display area DA2 are included in the display area DA, they may include a plurality of light-emitting areas EA.

The plurality of light-emitting areas EA may include light-emitting areas that emit three or more different colors of light. For example, the plurality of light-emitting areas EA may include a first light-emitting area that emits first-color light, a second light-emitting area that emits second-color light, and a third light-emitting area that emits third-color light.

For example, when the first-color light is red light, the second-color light is green light, and the third-color light is blue light, the first-color light-emitting area may be referred to as the first light-emitting area EA1, the second-color light-emitting area may be referred to as the second light-emitting area EA2, and the third-color light-emitting area may be referred to as the third light-emitting area EA3.

The first light-emitting area EA1, the second light-emitting area EA2, and the third light-emitting area EA3 may have the same size (light-emitting area size). Alternatively, at least one of the first light-emitting area EA1, the second light-emitting area EA2, and the third light-emitting area EA3 may have a different size (light-emitting area size) from the others.

As mentioned above, the first color, the second color, and the third color may be various different colors. For example, the first color, the second color, and the third color may include red, green, and blue, respectively. Hereinafter, for ease of explanation, an example is provided in which the first color is red, the second color is green, and the third color is blue. However, the embodiments are not limited thereto.

When the first color is red, the second color is green, and the third color is blue, among the sizes (light-emitting area sizes) of the first light-emitting area EA1, the second light-emitting area EA2, and the third light-emitting area EA3, the size of the third light-emitting area EA3 may be the largest.

The light-emitting device ED disposed in the first light-emitting area EA1 may include a light-emitting layer EML that emits red light. The light-emitting device ED disposed in the second light-emitting area EA2 may include a light-emitting layer EML that emits green light. The light-emitting device ED disposed in the third light-emitting area EA3 may include a light-emitting layer EML that emits blue light.

Among the light-emitting layers EML that emit red, green, and blue light, the organic material included in the light-emitting layer EML that emits blue light may deteriorate the most easily. Accordingly, by designing the third light-emitting area EA3 to be the largest, the current density supplied to the light-emitting device ED included in the third light-emitting area EA3 may be the lowest. Thus, the degree of deterioration of the light-emitting device ED in the third light-emitting area EA3 may become similar to the degree of deterioration of the light-emitting device ED in the first light-emitting area EA1 and the second light-emitting area EA2.

As a result, the degradation deviation among the light-emitting devices ED disposed in the first light-emitting area EA1, the second light-emitting area EA2, and the third light-emitting area EA3 may be eliminated or reduced, thereby improving image quality.

Referring to FIG. 4, the first display area DA1 may include a plurality of light-emitting areas EA and at least one transmissive area TA. The second display area DA2 may include a plurality of light-emitting areas EA.

Referring to FIG. 4, the first optical area OA1 may include a plurality of light-emitting areas EA and a plurality of first transmissive areas TA1. For example, each of the plurality of first transmissive areas TA1 may have various shapes such as circular, elliptical, polygonal, or irregular shapes. In one example, the plurality of first transmissive areas TA1 may have the same shape. In another example, some of the plurality of first transmissive areas TA1 may have a different shape from the others. The plurality of first transmissive areas TA1 may be separate areas or may be or may be connected areas.

Referring to FIG. 4, the second optical area OA2 may include a plurality of light-emitting areas EA and a plurality of second transmissive areas TA2. For example, each of the plurality of second transmissive areas TA2 included in the second optical area OA2 may have various shapes, such as circular, elliptical, polygonal, or irregular shapes. In one example, the plurality of second transmissive areas TA2 may have the same shape. In another example, some of the plurality of second transmissive areas TA2 may have a different shape from the others. The plurality of second transmissive areas TA2 may be separate areas or may be connected areas.

In one example, the first transmissive area TA1 and the second transmissive area TA2 may have the same shape. In another example, the first transmissive area TA1 and the second transmissive area TA2 may have different shapes.

Referring to FIG. 4, the second display area DA2 may be a non-transmissive area NTA. The second display area DA2 may include a non-transmissive area NTA in which a plurality of light-emitting areas EA are included. In other words, the entire second display area DA2 may be a non-transmissive area NTA, and the second display area DA2 may not include any transmissive areas TA.

The first display area DA1 may include a plurality of transmissive areas TA and low-transmissive areas LTA. The low-transmissive area LTA may refer to an area in the first display area DA1 excluding the plurality of transmissive areas TA. The low-transmissive area LTA may include a plurality of light-emitting areas EA.

The first optical area OA1 may include a low-transmissive area LTA, which comprises a plurality of light-emitting areas EA, and a plurality of first transmissive areas TA1. The low-transmissive area LTA included in the first optical area OA1 may be an area where no light is transmitted or an area where light is transmitted at a lower transmittance than the plurality of first transmissive areas TA1.

The second optical area OA2 may include a low-transmissive area LTA, which comprises a plurality of light-emitting areas EA, and a plurality of second transmissive areas TA2. The low-transmissive area LTA included in the second optical area OA2 may be an area where no light is transmitted or an area where light is transmitted at a lower transmittance than the plurality of second transmissive areas TA2.

Meanwhile, a plurality of touch electrodes, which function as a touch sensor, may be disposed in the first display area DA2 as well as in the second display area DA1. For example, a plurality of touch electrodes may be disposed in both the first optical area OA1 and the second optical area OA2 within the first display area DA1. In another example, the plurality of touch electrodes may not be disposed in either the first optical area OA1 or the second optical area OA2 within the first display area DA1. In yet another example, the plurality of touch electrodes may be disposed in one of the first optical area OA1 and the second optical area OA2 within the first display area DA1, but not in the other. However, the embodiments of the present disclosure are not limited thereto.

For instance, when the first electronic device 11, which overlaps with the first optical area OA1, is a camera (image sensor), and the second electronic device 12, which overlaps with the second optical area OA2, is a sensing sensor (e.g., an infrared sensor), the plurality of touch electrodes may be disposed in the first optical area OA1 but may not be disposed in the second optical area OA2.

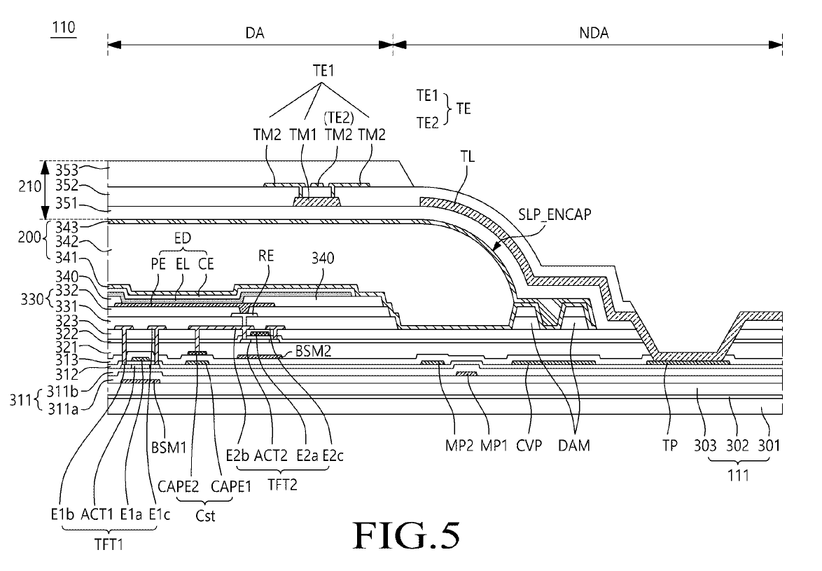

FIG. 5 is a cross-sectional view of a display panel 110 according to embodiments of the present disclosure.

Referring to FIG. 5, the display panel 110 according to embodiments of the present disclosure may comprise a substrate 111, a transistor portion, a light-emitting device portion, and an encapsulation portion. However, the embodiments of the present disclosure are not limited thereto.

The substrate 111 may be a single-layer or a multi-layer structure. If the substrate 111 is a multi-layer structure, it may comprise a first substrate 301, an intermediate substrate layer 302, and a second substrate 303. The intermediate substrate layer 302 may be positioned between the first substrate 301 and the second substrate 303. For example, each of the first substrate 301 and the second substrate 303 may be a polyimide (PI) layer. However, the embodiments of the present disclosure are not limited thereto. The intermediate substrate layer 302 may be an inorganic insulating layer. However, the embodiments of the present disclosure are not limited thereto. The intermediate substrate layer 302 may prevent electrical charges from affecting transistors disposed on the second substrate 303 when charges accumulate in the first substrate 301, which is a polyimide layer, as the second substrate 303 is also a polyimide layer. The intermediate substrate layer 302 may comprise a patterned area in certain areas. For instance, if the intermediate substrate layer 302 comprises an inorganic material, cracks may occur in areas where stress is concentrated or where bending occurs. Thus, the intermediate substrate layer 302 may be partially removed or patterned.

Additionally, the intermediate substrate layer 302 may prevent moisture from penetrating through the first substrate 301 and reaching the upper layers. For example, the intermediate substrate layer 302 may be formed as a single layer of silicon nitride (SiNx) or silicon oxide (SiOx) or as a multi-layer structure thereof. It may also be formed as a dual-layer structure of silicon dioxide (SiO₂) and silicon nitride (SiNx). However, the embodiments of the present disclosure are not limited thereto.

The transistor portion may comprise insulating layers 311, 312, 313, 321, 322, and 323 formed on the substrate 111, thin-film transistors TFT1 and TFT2, a storage capacitor Cst, and various electrodes and signal lines.

The thin-film transistors TFT1 and TFT2 included in the transistor portion may comprise a first thin-film transistor TFT1 and a second thin-film transistor TFT2.

The first thin-film transistor TFT1 may comprise a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be a drain electrode or a source electrode. Hereinafter, for convenience of explanation, the first electrode E1a will be referred to as the first gate electrode E1a, the second electrode E1b as the first source electrode E1b, and the third electrode E1c as the first drain electrode E1c. However, the embodiments of the present disclosure are not limited thereto.

The first active layer ACT1 may comprise a first semiconductor material. For example, the first semiconductor material may comprise an oxide semiconductor, amorphous silicon, polysilicon, or low-temperature polysilicon (LTPS), but the embodiments of the present disclosure are not limited thereto. The first thin-film transistor TFT1 may be implemented as a p-channel transistor or an n-channel transistor, but the embodiments of the present disclosure are not limited thereto.

The second thin-film transistor TFT2 may comprise a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be a drain electrode or a source electrode. Hereinafter, for convenience of explanation, the fourth electrode E2a will be referred to as the second gate electrode E2a, the fifth electrode E2b as the second source electrode E2b, and the sixth electrode E2c as the second drain electrode E2c. However, the embodiments of the present disclosure are not limited thereto.

The second active layer ACT2 may comprise a second semiconductor material. For example, the second semiconductor material may comprise an oxide semiconductor, amorphous silicon, polysilicon, or low-temperature polysilicon (LTPS), but the embodiments of the present disclosure are not limited thereto. The second thin-film transistor TFT2 may be implemented as a p-channel transistor or an n-channel transistor, but the embodiments of the present disclosure are not limited thereto.

The types of semiconductor materials used for each of the first active layer ACT1 of the first thin-film transistor TFT1 and the second active layer ACT2 of the second thin-film transistor TFT2 may be as follows.

For example, the first active layer ACT1 of the first thin-film transistor TFT1 and the second active layer ACT2 of the second thin-film transistor TFT2 may comprise an oxide semiconductor material. In another example, the first active layer ACT1 of the first thin-film transistor TFT1 and the second active layer ACT2 of the second thin-film transistor TFT2 may comprise a low-temperature polysilicon semiconductor material. In yet another example, the first active layer ACT1 of the first thin-film transistor TFT1 may comprise a low-temperature polysilicon semiconductor material, while the second active layer ACT2 of the second thin-film transistor TFT2 may comprise an oxide semiconductor material. In yet another example, the first active layer ACT1 of the first thin-film transistor TFT1 may comprise an oxide semiconductor material, while the second active layer ACT2 of the second thin-film transistor TFT2 may comprise a low-temperature polysilicon semiconductor material.

The application of transistors within the display area DA may be as follows.

For example, all transistors within each subpixel SP may be implemented as the first thin-film transistor TFT1. In another example, all transistors within each subpixel SP may be implemented as the second thin-film transistor TFT2. In yet another example, among all transistors within each subpixel SP, some may be implemented as the first thin-film transistor TFT1, while others may be implemented as the second thin-film transistor TFT2. That is, each subpixel SP may comprise at least one first thin-film transistor TFT1 and at least one second thin-film transistor TFT2.

If some transistors within each subpixel SP are implemented as the first thin-film transistor TFT1 while others are implemented as the second thin-film transistor TFT2, the following examples may be possible.

For example, in each subpixel SP, the driving transistor DT may be implemented as the first thin-film transistor TFT1, while other transistors different from the driving transistor DT (e.g., a scan transistor ST, a light-emission control transistor, etc.) may be implemented as the second thin-film transistor TFT2.

In another example, in each subpixel SP, the driving transistor DT may be implemented as the second thin-film transistor TFT2, while other transistors different from the driving transistor DT (e.g., a scan transistor ST, a light-emission control transistor, etc.) may be implemented as the first thin-film transistor TFT1.

In FIG. 5, the second thin-film transistor TFT2, which is connected to the pixel electrode PE of the light-emitting device ED, may be either the driving transistor DT or another transistor different from the driving transistor DT, depending on the configuration of the subpixel circuit SPC. For example, in FIG. 5, the second thin-film transistor TFT2, which is connected to the pixel electrode PE of the light-emitting device ED, may be a light-emission control transistor connected between the driving transistor DT and the light-emitting device ED. In another example, in FIG. 5, although the driving transistor DT connected to the light-emitting device ED is illustrated as being positioned above other transistors such as the scan transistor ST and the light-emission control transistor, the embodiments of the present disclosure are not limited thereto. The driving transistor DT connected to the light-emitting device ED may be positioned below other transistors such as the scan transistor ST and the light-emission control transistor.

The application of transistors within the non-display area NDA may be as follows.

For example, the active layers of transistors included in the gate driver circuit 130 of a gate-in-panel (GIP) type may be formed of an oxide semiconductor material. In another example, the active layers of transistors included in the gate driver circuit 130 of a gate-in-panel (GIP) type may formed of a low-temperature polysilicon semiconductor material. Another example is that, among the transistors included in the gate driving circuit 130 of the gate-in-panel (GIP) type, some of the active layers may be formed of a low-temperature polycrystalline silicon (LTPS) semiconductor material, while others may be formed of an oxide semiconductor material.

The second active layer ACT2 of the second thin-film transistor TFT2 may be positioned higher from the substrate 111 than the first active layer ACT1 of the first thin-film transistor TFT1.

A first buffer layer 311 is disposed below the first active layer ACT1 of the first thin-film transistor TFT1, and a second buffer layer 321 may be disposed below the second active layer ACT2 of the second thin-film transistor TFT2. For example, the first active layer ACT1 of the first thin-film transistor TFT1 is located on the first buffer layer 311, and the second active layer ACT2 of the second thin-film transistor TFT2 may be located on the second buffer layer 321. The second buffer layer 321 may be positioned higher than the first buffer layer 311.

A storage capacitor Cst may be arranged within various metal layers in the display panel 110. For example, the storage capacitor Cst may include a first capacitor electrode CAPE1 and a second capacitor electrode CAPE2.

The light-emitting device portion may include a plurality of light-emitting devices ED disposed on a planarization layer 330. Each of the light-emitting devices ED may include a pixel electrode PE, an intermediate layer EL, and a common electrode CE.

The encapsulation portion may include an encapsulation layer 200 on the plurality of light-emitting devices ED. The encapsulation layer 200 may be a single layer or a multilayer; however, the embodiments described in this specification are not limited thereto. In addition to the encapsulation layer 200, the encapsulation portion may further include at least one dam DAM to prevent the material forming the encapsulation layer 200 from overflowing. In particular, when a second encapsulation layer 342 included in the encapsulation layer 200 is an organic encapsulation layer made of an organic material, the dam DAM may prevent the organic material from overflowing.

Hereinafter, with reference to FIG. 5, the structure or vertical structure of the display panel 110 according to embodiments of this specification will be described in more detail.

Referring to FIG. 5, a first buffer layer 311 may be disposed on the substrate 111. The first buffer layer 311 may be a single layer or a multilayer; however, the embodiments described in this specification are not limited thereto. When the first buffer layer 311 is a multilayer, it may include a lower buffer layer 311a and an upper buffer layer 311b.

A first active layer ACT1 of the first thin-film transistor TFT1 may be disposed on the first buffer layer 311. The first active layer ACT1 may include a channel area where a channel is formed, a source connection area on one side of the channel area, and a drain connection area on the other side of the channel area.

A first gate insulating layer 312 may be disposed on the first active layer ACT1 of the first thin-film transistor TFT1. A first gate electrode E1a of the first thin-film transistor TFT1 may be disposed on the first gate insulating layer 312. A first interlayer insulating layer 313 may be disposed on the first gate electrode E1a of the first thin-film transistor TFT1. Here, the metal layer in which the first gate electrode E1a of the first thin-film transistor TFT1 is disposed may be referred to as the first gate metal layer.

A second buffer layer 321 may be disposed on the first interlayer insulating layer 313.

A second active layer ACT2 of the second thin-film transistor TFT2 may be disposed on the second buffer layer 321. The second active layer ACT2 may include a channel area where a channel is formed, a source connection area on one side of the channel area, and a drain connection area on the other side of the channel area.

A second gate insulating layer 322 may be disposed on the second active layer ACT2 of the second thin-film transistor TFT2. A second gate electrode E2a of the second thin-film transistor TFT2 may be disposed. A second interlayer insulating layer 323 may be disposed on the second gate electrode E2a of the second thin-film transistor TFT2. Here, the second gate electrode E2a of the second thin-film transistor TFT2 may be referred to as the second gate metal layer.

The first source electrode E1b and the first drain electrode E1c of the first thin-film transistor TFT1, and the second source electrode E2b and the second drain electrode E2c of the second thin-film transistor TFT2 may be disposed on the second interlayer insulating layer 323.

The first source electrode E1b and the first drain electrode E1c of the first thin-film transistor TFT1 may be connected to the source connection area and the drain connection area of the first active layer ACT1 through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin-film transistor TFT2 may be connected to the source connection area and the drain connection area of the second active layer ACT2 through holes in the second interlayer insulating layer 323 and the second gate insulating layer 322.

The first source electrode E1b and the first drain electrode E1c of the first thin-film transistor TFT1, and the second source electrode E2b and the second drain electrode E2c of the second thin-film transistor TFT2 may include a first source-drain metal and may be disposed within a first source-drain metal layer.

Referring to FIG. 5, for example, a storage capacitor Cst may be formed by a first capacitor electrode CAPE1 and a second capacitor electrode CAPE2. In some cases, the storage capacitor Cst may be formed by three or more capacitor electrodes or may be in a form where two or more capacitors are connected in parallel.

Each of the first capacitor electrode CAPE1 and the second capacitor electrode CAPE2 may be disposed in various metal layers within the display panel 110.

For example, the first capacitor electrode CAPE1 may include the same first gate metal as the first gate electrode E1a of the first thin-film transistor TFT1 on the first gate insulating layer 312 and may be disposed within the first gate metal layer; however, the embodiments described in this specification are not limited thereto. For example, the second capacitor electrode CAPE2 may be disposed on the first interlayer insulating layer 313.

The second source electrode E2b of the second thin-film transistor TFT2 may also be electrically connected to the second capacitor electrode CAPE2 through holes in the second interlayer insulating layer 323, the second gate insulating layer 322, and the second buffer layer 321.

For example, when the subpixel SP is configured as shown in FIG. 3, the first thin-film transistor TFT1 may be the scanning transistor ST in FIG. 3, and the second thin-film transistor TFT2 may be the driving transistor DT in FIG. 3.

The transistor portion may further include at least one additional metal pattern MP1 or MP2. For example, the first metal pattern MP1 may be disposed between the lower buffer layer 311a and the upper buffer layer 311b included in the first buffer layer 311; however, the embodiments described in this specification are not limited thereto. The second metal pattern MP2 may include the same first gate metal as the first gate electrode E1a of the first thin-film transistor TFT1 and may be disposed within the first gate metal layer; however, the embodiments described in this specification are not limited thereto.

Each of the first metal pattern MP1 and the second metal pattern MP2 may be disposed in the display area DA or the non-display area NDA.

Referring to FIG. 5, the transistor portion may further include a first shield pattern BSM1 disposed on the substrate 111. The first shield pattern BSM1 may overlap with the first active layer ACT1 of the first thin-film transistor TFT1. The first shield pattern BSM1 may be disposed below the first active layer ACT1 of the first thin-film transistor TFT1. For example, the first shield pattern BSM1 may be disposed between the substrate 111 and the first buffer layer 311, or between the lower buffer layer 311a and the upper buffer layer 311b.

The transistor portion may further include a second shield pattern BSM2 disposed on the substrate 111. The second shield pattern BSM2 may overlap with the second active layer ACT2 of the second thin-film transistor TFT2. The second shield pattern BSM2 may be disposed below the second active layer ACT2 of the second thin-film transistor TFT2. For example, the second shield pattern BSM2 may be disposed within the metal layer between the first interlayer insulating layer 313 and the second buffer layer 321. The second shield pattern BSM2 may be disposed within the same metal layer as the second capacitor electrode CAPE2; however, the embodiments described in this specification are not limited thereto. As another example, the second shield pattern BSM2 may be disposed within the same first gate metal layer as the first gate electrode E1a of the first thin-film transistor TFT1.

Referring to FIG. 5, the transistor portion may further include a common driving signal layer CVP to which a common driving signal is applied. The common driving signal layer CVP may be disposed in the display area DA or the non-display area NDA.

For example, the common driving signal applied to the common driving signal layer CVP may also be referred to as a power signal and may include at least one of a driving voltage VDD and a reference voltage VSS. The driving voltage VDD may also be referred to as a high-potential driving voltage (high-potential power voltage or high-potential voltage), and the reference voltage VSS may also be referred to as a low-potential driving voltage (low-potential power voltage or low-potential voltage).

The planarization layer 330 may be disposed on the first thin-film transistor TFT1 and the second thin-film transistor TFT2, and may be disposed below the light-emitting device ED. The planarization layer 330 may be an organic insulating layer including an organic insulating material.

For example, the planarization layer 330 may be composed of a single layer. As another example, the planarization layer 330 may include two layers. The planarization layer 330 may include a first planarization layer 331 and a second planarization layer 332. As another example, the planarization layer 330 may include three or more layers. The embodiments described in this specification are not limited thereto.

Referring to FIG. 5, the first planarization layer 331 may be disposed on the first source electrode E1b and the first drain electrode E1c of the first thin-film transistor TFT1, and on the second source electrode E2b and the second drain electrode E2c of the second thin-film transistor TFT2. For example, the first planarization layer 331 may be disposed on the first thin-film transistor TFT1 and the second thin-film transistor TFT2. For example, the first planarization layer 331 may be disposed while covering both the first thin-film transistor TFT1 and the second thin-film transistor TFT2.

Referring to FIG. 5, a connection electrode RE may be disposed on the first planarization layer 331. The connection electrode RE may electrically connect the second source electrode E2b of the second thin-film transistor TFT2 to the pixel electrode PE.

The connection electrode RE may be electrically connected to the second source electrode E2b of the second thin-film transistor TFT2 through a hole in the first planarization layer 331. The second source electrode E2b of the second thin-film transistor TFT2 may be electrically connected to the second capacitor electrode CAPE2 of the storage capacitor Cst.

The connection electrode RE may be disposed within the second source-drain metal layer on the first planarization layer 331 and may include a second source-drain metal.

The second planarization layer 332 may be disposed on the connection electrode RE.

Referring to FIG. 5, the light-emitting device portion may be disposed on the second planarization layer 332. The light-emitting device ED may be formed on the second planarization layer 332. The light-emitting device ED may include a pixel electrode PE, an intermediate layer EL, and a common electrode CE. The emission area of the light-emitting device ED may be formed in a region where the pixel electrode PE, the intermediate layer EL, and the common electrode CE overlap and come into contact.

The pixel electrode PE may be disposed on the second planarization layer 332. The pixel electrode PE may be electrically connected to the connection electrode RE through a hole in the second planarization layer 332.

A bank 340 may be disposed on the pixel electrode PE. The opening of the bank 340 may expose a portion of the pixel electrode PE to form an emission area. The opening of the bank 340 may overlap with a portion of the pixel electrode PE.

For example, the bank 340 may be formed of a material including a black pigment or an organic material such as benzocyclobutene resin, polyimide resin, acrylic resin, or a photosensitive polymer; however, the embodiments described in this specification are not limited thereto. When the bank 340 is formed of a material including a black pigment or black dye, it may be referred to as a black bank. If the bank 340 is formed of a material containing a black pigment or black dye, it may block external light or reflected light, thereby improving the luminance of the display apparatus 100.

The intermediate layer EL of the light-emitting device ED may be disposed on a portion of the pixel electrode PE and the bank 340. The common electrode CE may be disposed on the intermediate layer EL.

Referring to FIG. 5, the encapsulation portion may be disposed on the light-emitting device portion and may be positioned on the common electrode CE. The encapsulation portion may include an encapsulation layer 200 formed on the common electrode CE.

The encapsulation layer 200 may prevent moisture or oxygen from penetrating into the light-emitting device ED. For example, the encapsulation layer 200 may prevent moisture or oxygen from penetrating into the organic material included in the intermediate layer EL of the light-emitting device ED. The encapsulation layer 200 may be formed as a single layer or a multilayer; however, the embodiments described in this specification are not limited thereto.

For example, the encapsulation layer 200 may include a first encapsulation layer 341, a second encapsulation layer 342, and a third encapsulation layer 343; however, the embodiments described in this specification are not limited thereto. For example, the first encapsulation layer 341 and the third encapsulation layer 343 may include an inorganic encapsulation layer, and the second encapsulation layer 342 may include an organic encapsulation layer; however, the embodiments described in this specification are not limited thereto.

The display panel 110 according to embodiments of this specification may include a built-in touch sensor. In this case, the display panel 110 according to embodiments of this specification may be disposed on the encapsulation layer 200 and may include a touch sensor layer 210 in which a touch sensor is formed.

Referring to FIG. 5, the touch sensor layer 210 may include a plurality of touch electrodes TE corresponding to the touch sensor and may include at least one touch metal layer for forming the plurality of touch electrodes TE.

For example, the touch sensor layer 210 may include a first touch metal layer in which a plurality of first touch metals TM1 are disposed, and a second touch metal layer in which a plurality of second touch metals TM2 are disposed, in order to form the plurality of touch electrodes TE. In this case, the touch sensor layer 210 may further include a touch interlayer insulating layer 352 disposed between the first touch metal layer and the second touch metal layer.

For example, one of the first touch metal layer and the second touch metal layer may be a sensor metal layer, and the other may be a bridge metal layer.

As one example, the first touch metal layer may be a bridge metal layer, and the second touch metal layer may be a sensor metal layer. In this case, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are sensor metals. For example, two or more second touch metals TM2 and at least one first touch metal TM1 may constitute a first touch electrode TE1. In this case, two or more second touch metals TE2 may be electrically connected by at least one first touch metal TM1.

As another example, the first touch metal layer may be a sensor metal layer, and the second touch metal layer may be a bridge metal layer. In this case, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are sensor metals.

As another example, each of the first touch metal layer and the second touch metal layer may be a sensor metal layer and a bridge metal layer. For example, the first touch metal layer may include both a sensor metal layer and a bridge metal layer, and the second touch metal layer may also include both a sensor metal layer and a bridge metal layer. In this case, the plurality of first touch metals TM1 disposed in the first touch metal layer may include both sensor metals and bridge metals, and the plurality of second touch metals TM2 disposed in the second touch metal layer may also include both sensor metals and bridge metals.

Referring to FIG. 5, the touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and a touch interlayer insulating layer 352 may be disposed on the first touch metal layer.

Referring to FIG. 5, the touch sensor layer 210 may further include a touch protection layer 353 disposed to cover the touch metal layer. For example, the touch protection layer 353 may be disposed on the second touch metal layer.

For example, the touch buffer layer 351 may be an inorganic layer including an inorganic insulating material or an organic layer including an organic insulating material. The touch interlayer insulating layer 352 may be an inorganic layer including an inorganic insulating material or an organic layer including an organic insulating material. The touch protection layer 353 may be an inorganic layer including an inorganic insulating material or an organic layer including an organic insulating material.

For example, at least one of the touch buffer layer 351 and the touch interlayer insulating layer 352 may be extended from the display area DA to the non-display area NDA. The touch protection layer 353 may be extended from the display area DA to the non-display area NDA.

A touch routing line TL may electrically connect a touch electrode TE and a touch pad TP. The touch routing line TL may be composed of at least one of a first touch metal TM1 and a second touch metal TM2.

For example, the touch routing line TL may be composed of the first touch metal TM1, the second touch metal TM2, or both the first touch metal TM1 and the second touch metal TM2. When a single touch routing line TL is composed of both the first touch metal TM1 and the second touch metal TM2, the first touch metal TM1 and the second touch metal TM2 forming the touch routing line TL may be electrically connected through a hole in the touch interlayer insulating layer 352.

For example, a single touch routing line TL may include multiple line sections, each of which may be either a single line section or a dual line section. Here, a single line section is a line section with a single signal path, while a dual line section is a line section with two signal paths connected in parallel.

The touch routing line TL may be disposed along the slope SLP_ENCAP of the encapsulation layer 200 and may extend over the dam DAM to the touch pad TP.

The touch buffer layer 351 may have an opening that exposes at least a portion of the touch pad TP. The touch routing line TL may be electrically connected to the touch pad TP through an opening in the touch buffer layer 351. The touch interlayer insulating layer 352 may be disposed on the touch routing line TL and may extend to the area where the touch pad TP is disposed. The touch protection layer 353 may be disposed only in the display area DA or may extend to the non-display area NDA, where it may also be disposed on the top of the touch routing line TL. In some cases, the touch protection layer 353 may further extend to the top of the touch pad TP.”

Each of the plurality of touch electrodes TE may be a mesh-type electrode having multiple openings. In this case, each of the plurality of touch electrodes TE may be composed of at least one second touch metal TM2; however, the embodiments described in this specification are not limited thereto.

For example, the plurality of touch electrodes TE may include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor may be electrically connected through at least one first touch metal TM1, which is a bridge metal. For example, two spaced-apart second touch metals TM2 may be electrically connected by a first touch metal TM1 to form a single first touch electrode TE1.

Referring to FIG. 5, the plurality of first touch metals TM1 and the plurality of second touch metals TM2 may be arranged so as not to overlap with the light-emitting device ED. The plurality of first touch metals TM1 and the plurality of second touch metals TM2 may overlap with the bank 340. Accordingly, the emission efficiency of the light-emitting device ED may be improved.

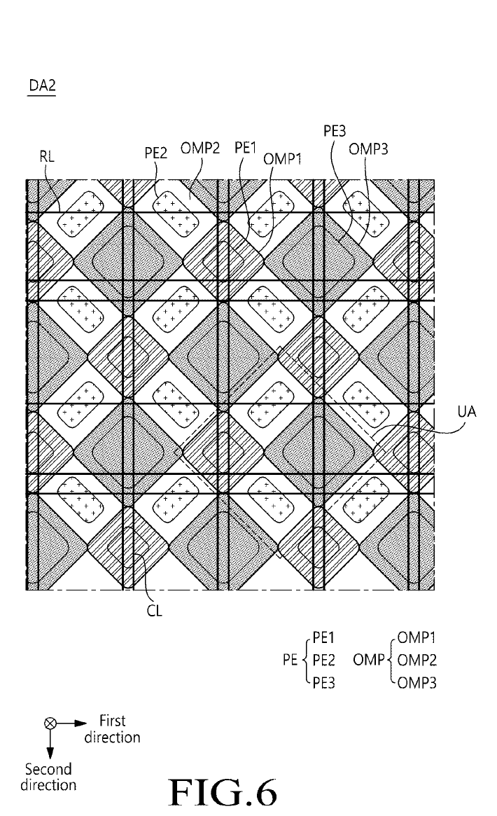

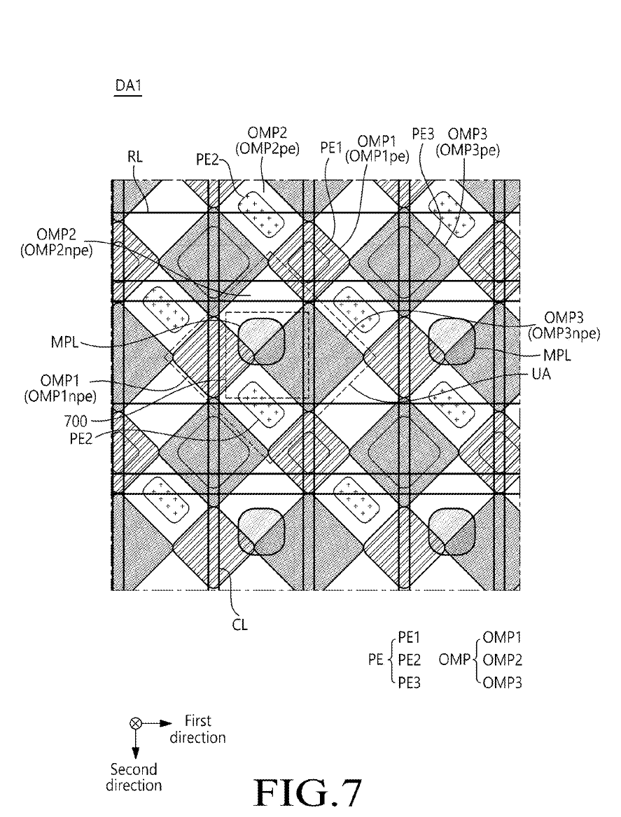

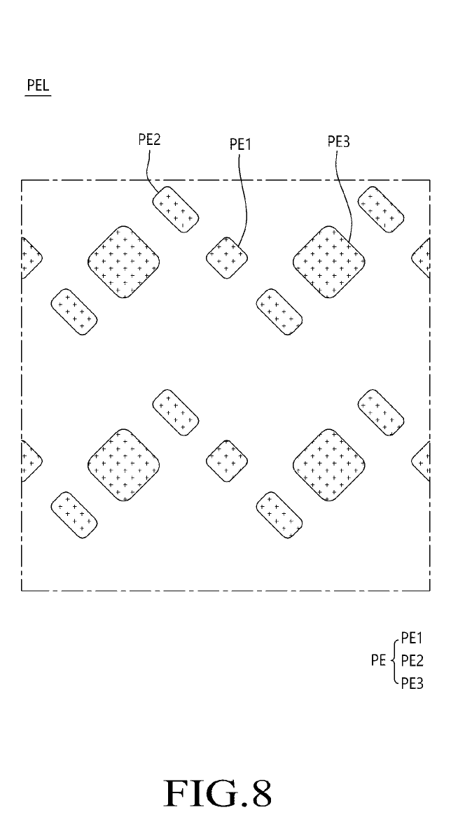

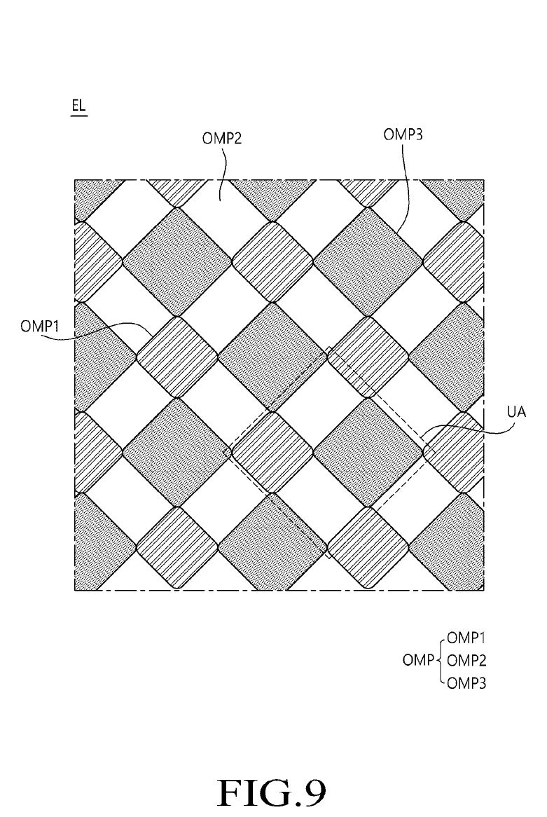

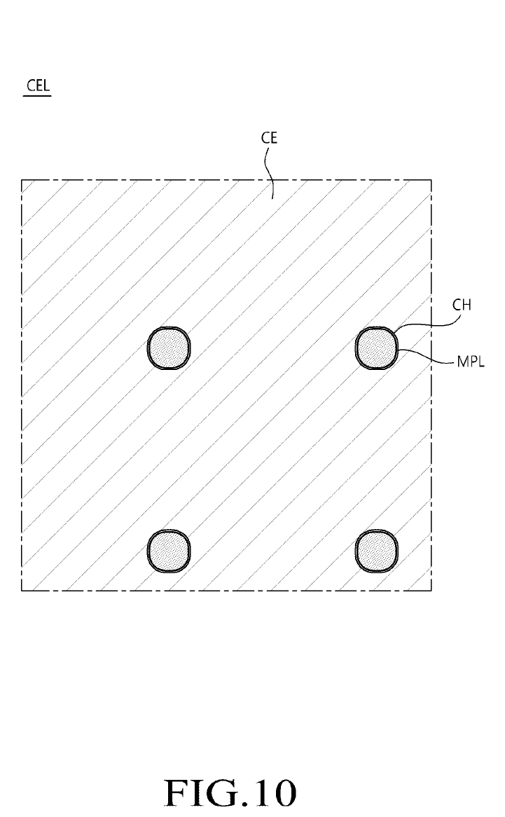

FIG. 6 is a plan view of a second display area DA2 of a display panel according to embodiments of this specification. FIG. 7 is a plan view of a first display area DA1 of the display panel 110 according to embodiments of this specification. FIG. 8 illustrates pixel electrodes PE in FIG. 7, FIG. 9 illustrates organic material patterns OMP in FIG. 7, and FIG. 10 illustrates the common electrode CE and light transmission patterns MPL in FIG. 7. Hereinafter, FIG. 1 to FIG. 5 may also be referenced.

As described above, the display panel 110 according to embodiments of this specification may include a substrate 111, an insulating layer disposed on the substrate 111, a plurality of pixel electrodes PE disposed on the insulating layer, an intermediate layer EL disposed on the plurality of pixel electrodes PE, and a common electrode CE disposed on the intermediate layer EL. Here, the intermediate layer EL is a layer disposed between the pixel electrode PE and the common electrode CE and may be composed of an organic material. Accordingly, the intermediate layer EL is also referred to as an organic layer in this specification.

According to embodiments of this specification, the substrate 111 of the display panel 110 may include a display area DA where an image is displayed and a non-display area NDA where an image is not displayed. The display area DA may include a first display area DA1 and a second display area DA2 located outside the first display area DA1.

As described above, the first display area DA1 is an area that overlaps with an electronic device 10 that performs a predetermined operation by receiving light transmitted through the display panel 110. The first display area DA1 may allow light to pass through or may have a certain level of light transmittance.

The electronic device 10 may overlap with the first display area DA1, be positioned below the substrate 111, receive light transmitted through the first display area DA1, and perform a predetermined operation using the received light. For example, the light used by the electronic device 10 to perform an operation may be one of visible light, infrared light, and ultraviolet light, and may also include electromagnetic waves of various wavelengths. For example, the electronic device 10 may include at least one of a camera (image sensor) and various sensing sensors.

Referring to FIG. 6 and FIG. 7, the first display area DA1 and the second display area DA2 may each include first signal lines RL extending in a first direction and second signal lines CL extending in a second direction different from the first direction. For example, the first signal lines RL may include various gate lines. The second signal lines CL may include data lines and power lines.

Referring to FIG. 6 and FIG. 7, the first display area DA1 may include a plurality of emission areas EA and at least one transmissive area. The second display area DA2 may include a plurality of emission areas EA.

Referring to FIG. 6 and FIG. 7, a plurality of pixel electrodes PE may be positioned in the plurality of emission areas included in the first display area DA1. A plurality of pixel electrodes PE may be positioned in the plurality of emission areas included in the second display area DA2.

Referring to FIG. 6 and FIG. 7, in each of the first display area DA1 and the second display area DA2, the organic layer EL may include a plurality of organic material patterns OMP. That is, the organic layer EL may be patterned into multiple pieces, which are referred to as a plurality of organic material patterns OMP. Accordingly, the organic layer EL may appear in a checkered pattern.

Referring to FIG. 6, in the second display area DA2, the plurality of organic material patterns OMP may overlap with the plurality of pixel electrodes PE. That is, a single organic material pattern OMP may be disposed on and overlap with a single pixel electrode PE.

Referring to FIG. 7, in the first display area DA1, some of the plurality of organic material patterns OMP may overlap with the pixel electrodes PE, while others may not overlap with the pixel electrodes PE.

Referring to FIG. 7 to FIG. 10, the plurality of pixel electrodes PE may be disposed within the pixel electrode layer PEL, the plurality of organic material patterns OMP may be disposed within the organic layer EL, and the common electrode CE may be disposed within the common electrode layer CEL.

Referring to FIG. 7 to FIG. 9, in the first display area (DA1), among the plurality of pixel electrodes (PE), the plurality of organic material patterns (OMP) may include at least two organic material patterns (OMP) that overlap with at least two pixel electrodes (PE) disposed in the first display area (DA1), and at least two organic material patterns (OMP) that do not overlap with the at least two pixel electrodes (PE).

Accordingly, in the first display area DA1, at least two organic material patterns OMP among the plurality of organic material patterns OMP may be disposed on and overlap with at least two pixel electrodes PE disposed in the first display area DA1. Meanwhile, at least two other organic material patterns OMP among the plurality of organic material patterns OMP may be disposed in regions where at least two pixel electrodes PE are not disposed in the first display area DA1, and thus may not overlap with the at least two pixel electrodes PE.

Since each of the at least two organic material patterns OMP overlapping with the at least two pixel electrodes PE is involved in forming the light-emitting device ED, they may include a first common intermediate layer COM1, an emission layer EML, and a second common intermediate layer COM2.

Each of the at least two organic material patterns OMP that do not overlap with the at least two pixel electrodes PE does not need to form a light-emitting device ED.

However, according to embodiments of this specification, although each of the at least two organic material patterns OMP that do not overlap with the at least two pixel electrodes PE does not need to form a light-emitting device ED, they may still include the first common intermediate layer COM1, the emission layer EML, and the second common intermediate layer COM2. That is, each of the at least two organic material patterns OMP overlapping with the at least two pixel electrodes PE may include the emission layer EML. Similarly, each of the at least two organic material patterns OMP that do not overlap with the at least two pixel electrodes PE may also include the emission layer EML.

As described above, in the first display area DA1, although the organic material pattern OMP that does not overlap with the pixel electrode PE does not need to form a light-emitting device ED, it still includes the first common intermediate layer COM1, the emission layer EML, and the second common intermediate layer COM2. Accordingly, the organic material pattern OMP overlapping with the pixel electrode PE and the organic material pattern OMP that does not overlap with the pixel electrode PE may be formed in the same manner. That is, the organic layer EL in the first display area DA1 and the organic layer EL in the second display area DA2 may be formed in the same manner. As a result, the process of forming the organic layer EL may be simplified.

Referring to FIG. 7 to FIG. 9, in the first display area DA1, the area where at least two pixel electrodes PE are disposed may correspond to at least two emission areas. In the first display area DA1, the area where the pixel electrodes PE are not disposed may include a low-transmittance area excluding the at least two emission areas, and at least one transmissive area distinguishable from the low-transmittance area. The at least one transmissive area may have a higher light transmittance than the low-transmittance area and thus may be distinguished from the low-transmittance area.

Referring to FIG. 7 and FIG. 10, the display panel 110 according to embodiments of this specification may be disposed on the organic layer EL and may further include at least two light transmission patterns MPL that are spaced apart from each other and disposed in the first display area DA1.

The at least two light transmission patterns MPL may be formed of a material that suppresses the formation of the common electrode CE on the at least two light transmission patterns MPL (common electrode formation suppression material). Through this, the common electrode CE may be formed in a very small amount or may not be formed at all in the area where the at least two light transmission patterns MPL are formed.

For example, the common electrode formation suppression material may include an organic material. That is, the at least two light transmission patterns MPL may include an organic material. The organic material may include an inorganic material such as a metal. For example, the at least two light transmission patterns MPL may be formed of a compound containing fluorine in its molecular structure.

In other words, during the process of manufacturing the display panel 110, a light transmission pattern MPL may be formed in the transmissive area (TA1, TA2 in FIG. 4) where high light transmittance is required in the first display area DA1, and the common electrode material may be deposited. Accordingly, the common electrode material may not be deposited or may be deposited in a very small amount on the light transmission pattern MPL. As a result, in the area where the light transmission pattern MPL is formed (i.e., the transmissive area), an opening CH of the common electrode CE may be formed.

Since the common electrode material, which is a type of metal, is not formed in the transmissive area where high light transmittance is required, the first display area DA1 may have a high light transmittance.

Furthermore, as the first display area DA1 has high light transmittance, the amount of light passing through the first display area DA1 may increase. As a result, the electronic device 10 overlapping with the first display area DA1 of the display panel 110 may accurately perform a predetermined operation by using the large amount of light transmitted through the first display area DA1. For example, when the electronic device 10 is a camera (image sensor), the electronic device 10 may obtain a high-quality image. Additionally, when the electronic device 10 is a sensing sensor such as an infrared sensor, the electronic device 10 may perform a more accurate sensing operation using the large amount of light passing through the first display area DA1. Moreover, as the electronic device 10 performs a sensing operation (e.g., image sensing, object detection) using a larger amount of light, the resolution for distinguishing between two adjacent points may improve. For example, an improvement in resolution may mean a reduction in the size of the point spread function (PSF). Accordingly, the camera may obtain a high-quality image, and the sensing sensor may achieve accurate sensing performance.

Referring to FIG. 7 and FIG. 10, an area where a single light transmission pattern MPL is formed may correspond to a transmissive area with high light transmittance. Here, the transmissive area may be the first transmissive area TA1 or the second transmissive area TA2 in FIG. 4.

Referring to FIG. 7 and FIG. 10, the common electrode CE may have at least two openings CH positioned in the first display area DA1.

Referring to FIG. 7 and FIG. 10, each of the at least two light transmission patterns MPL may be positioned inside each of the at least two openings CH or may be positioned to overlap with each of the at least two openings CH. For example, the at least two light transmission patterns MPL may appear to be disposed together with the common electrode CE within the common electrode layer CEL.

Referring to FIG. 7, at least a portion of at least one of the at least two light transmission patterns MPL may overlap with at least a portion of at least one of the at least two organic material patterns OMP that do not overlap with the at least two pixel electrodes PE.

Referring to FIG. 6, FIG. 7, and FIG. 8, in each of the first display area DA1 and the second display area DA2, the plurality of pixel electrodes PE may include at least two first pixel electrodes PE1 included in at least two first subpixels for emitting first-colored light, at least two second pixel electrodes PE2 included in at least two second subpixels for emitting second-colored light, and at least two third pixel electrodes PE3 included in at least two third subpixels for emitting third-colored light.

The first-colored light, the second-colored light, and the third-colored light may be different colors. For example, the first-colored light may be red light, the second-colored light may be green light, and the third-colored light may be blue light. However, the embodiments described in this specification are not limited thereto.

Referring to FIG. 6, FIG. 7, and FIG. 9, in each of the first display area DA1 and the second display area DA2, the plurality of organic material patterns OMP in the first display area DA1 may include a plurality of first organic material patterns OMP1 configured to emit first-colored light, a plurality of second organic material patterns OMP2 configured to emit second-colored light, and a plurality of third organic material patterns OMP3 configured to emit third-colored light.

The plurality of first organic material patterns OMP1 may be spaced apart from each other.

A second organic material pattern OMP2 or a third organic material pattern OMP3 may be disposed between two adjacent first organic material patterns OMP1 among the plurality of first organic material patterns OMP1.

The plurality of third organic material patterns OMP3 may be spaced apart from each other.

A first organic material pattern OMP1 or a second organic material pattern OMP2 may be disposed between two adjacent third organic material patterns OMP3 among the plurality of third organic material patterns OMP3.

As one example, among the plurality of second organic material patterns OMP2, two adjacent second organic material patterns OMP2 may be separated from each other by the surrounding first organic material patterns OMP1 and third organic material patterns OMP3. In this case, the edge of the first organic material pattern OMP1 and the edge of the third organic material pattern OMP3 may be in contact with each other.

As another example, among the plurality of second organic material patterns OMP2, two adjacent second organic material patterns OMP2 may not be separated but may be continuous. In this case, the edge of the first organic material pattern OMP1 and the edge of the third organic material pattern OMP3 may be spaced apart in a horizontal direction, and a portion of the second organic material pattern OMP2 may be extended and disposed in and be disposed in the space between the edge of the first organic material pattern OMP1 and the edge of the third organic material pattern OMP3.

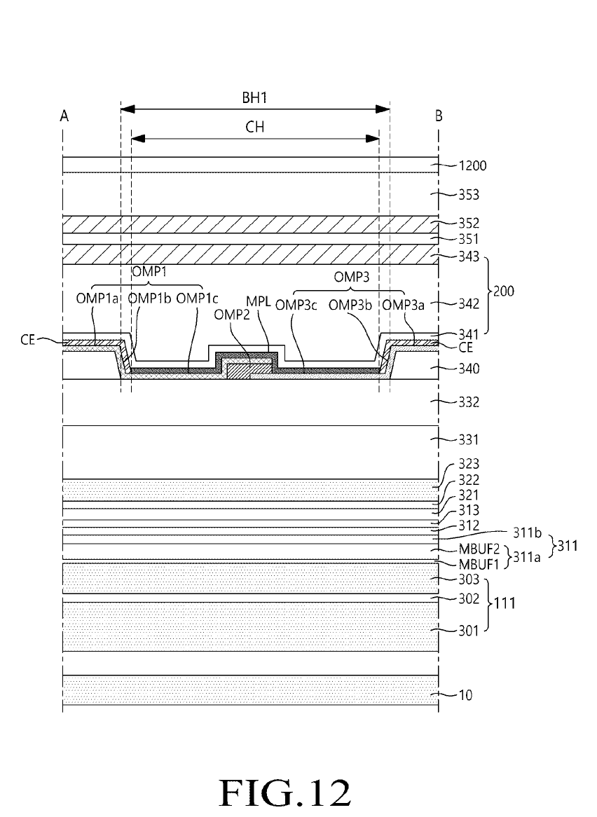

As another example, among the plurality of second organic material patterns OMP2, two adjacent second organic material patterns OMP2 may not be separated but may be continuous. In this case, the edge of the first organic material pattern OMP1 and the edge of the third organic material pattern OMP3 may be overlapped in a vertical direction, and a portion of the second organic material pattern OMP2 may be extended and disposed in the space (vertical overlap space) between the edge of the first organic material pattern OMP1 and the edge of the third organic material pattern OMP3 (see FIG. 12).

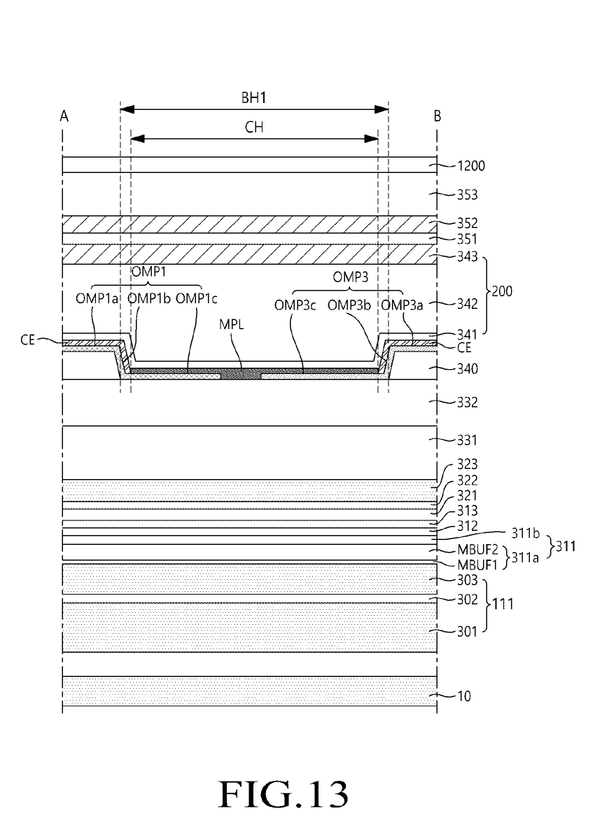

As another example, among the plurality of second organic material patterns OMP2, two adjacent second organic material patterns OMP2 may be separated from each other by a surrounding light transmission pattern MPL. In this case, the edge of the first organic material pattern OMP1 and the edge of the third organic material pattern OMP3 may be spaced apart from each other, and a portion of the light transmission pattern MPL may be interposed in the space between the edge of the first organic material pattern OMP1 and the edge of the third organic material pattern OMP3 (see FIG. 13).

Referring to FIG. 6, FIG. 7, and FIG. 9, each of the first display area DA1 and the second display area DA2 may include a plurality of unit areas UA. Each of the plurality of unit areas UA may include four organic material patterns OMP among the plurality of organic material patterns OMP. This is also the same in the second display area DA2.

For example, the four organic material patterns OMP may include one first organic material pattern OMP1, two second organic material patterns OMP2, and one third organic material pattern OMP3.

Referring to FIG. 7, FIG. 9, and FIG. 10, at least two light transmission patterns MPL may be disposed only in some of the plurality of unit areas UA.

Referring to FIG. 7, FIG. 9, and FIG. 10, among the at least two light transmission patterns MPL, a first light transmission pattern MPL may be disposed in a first unit area UA among the plurality of unit areas UA. A portion of each of the four organic material patterns OMP disposed in the first unit area UA may overlap with the first light transmission pattern MPL.

Referring to FIG. 7, in the first display area DA1, the plurality of first organic material patterns OMP1 may include at least two first organic material patterns OMP1pe that each overlap with at least two first pixel electrodes PE1 and at least two first organic material patterns OMP1npe that do not overlap with the at least two first pixel electrodes PE1.

Referring to FIG. 7, in the first display area DA1, the plurality of third organic material patterns OMP3 may include at least two third organic material patterns OMP3pe that each overlap with at least two third pixel electrodes PE3 and at least two third organic material patterns OMP3npe that do not overlap with the at least two third pixel electrodes PE3.

Referring to FIG. 7, in the first display area DA1, at least a portion of each of the at least two light transmission patterns MPL may overlap with at least a portion of at least one first organic material pattern OMP1npe among the at least two first organic material patterns OMP1npe that do not overlap with the at least two first pixel electrodes PE1, or at least a portion of at least one third organic material pattern OMP3npe among the at least two third organic material patterns OMP3npe that do not overlap with the at least two third pixel electrodes PE3. For example, in the first display area DA1, at least a portion of each of the at least two light transmission patterns MPL may overlap with at least a portion of at least one first organic material pattern OMP1npe among the at least two first organic material patterns OMP1npe that do not overlap with the at least two first pixel electrodes PE1, and at least a portion of at least one third organic material pattern OMP3npe among the at least two third organic material patterns OMP3npe that do not overlap with the at least two third pixel electrodes PE3.

Referring to FIG. 7, the plurality of second organic material patterns OMP2 may include at least two second organic material patterns OMP2pe that each overlap with at least two second pixel electrodes PE2 and at least two second organic material patterns OMP2npe that do not overlap with the at least two second pixel electrodes PE2.

At least a portion of each of the at least two light transmission patterns MPL may overlap with at least a portion of at least one second organic material pattern OMP2npe among the at least two second organic material patterns OMP2npe that do not overlap with the at least two second pixel electrodes PE2.

For example, in the first display area DA1, at least a portion of each of the at least two light transmission patterns MPL may overlap with at least a portion of at least one first organic material pattern OMP1npe among the at least two first organic material patterns OMP1npe that do not overlap with the at least two first pixel electrodes PE1. It may also overlap with at least a portion of at least one third organic material pattern OMP3npe among the at least two third organic material patterns OMP3npe that do not overlap with the at least two third pixel electrodes PE3. Additionally, it may overlap with at least a portion of at least one second organic material pattern OMP2npe among the at least two second organic material patterns OMP2npe that do not overlap with the at least two second pixel electrodes PE2.

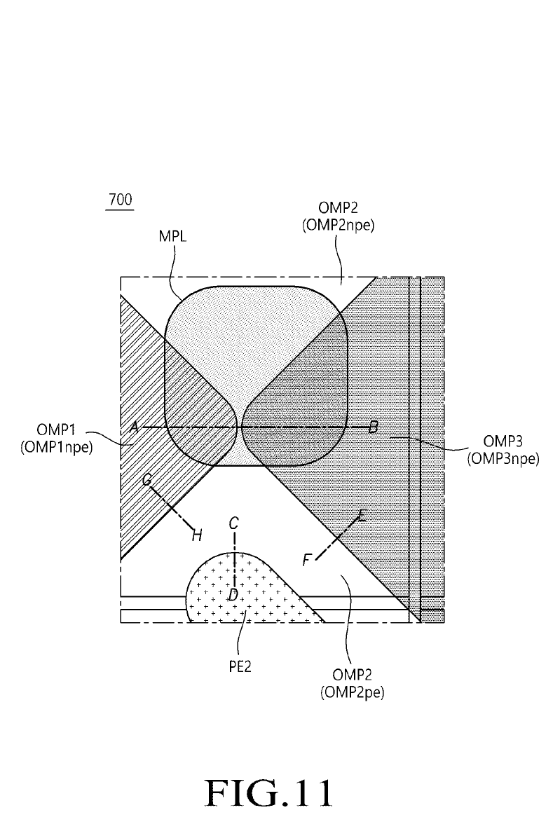

FIG. 11 is an enlarged plan view of a partial area 700 of FIG. 7.

FIG. 11 illustrates a partial area 700 included in the first display area DA1.

Referring to FIG. 11, the light transmission pattern MPL may include a first portion overlapping with the first organic material pattern OMP1, a second portion overlapping with the second organic material pattern OMP2, and a third portion overlapping with the third organic material pattern OMP3.

Referring to FIG. 11, as one example, the two second organic material patterns OMP2 overlapping with the light transmission pattern MPL may include a second organic material pattern OMP2pe that overlaps with the second pixel electrode PE2 and a second organic material pattern OMP2npe that does not overlap with the second pixel electrode PE2. As another example, both of the two second organic material patterns OMP2 overlapping with the light transmission pattern MPL may be second organic material patterns OMP2npe that do not overlap with the second pixel electrode PE2.

Referring to FIG. 11, the first organic material pattern OMP1 overlapping with the light transmission pattern MPL may be a first organic material pattern OMP1npe that does not overlap with the first pixel electrode PE1.

Referring to FIG. 11, the third organic material pattern OMP3 overlapping with the light transmission pattern MPL may be a third organic material pattern OMP3npe that does not overlap with the third pixel electrode PE3.

Hereinafter, the vertical structure of the display panel 110 will be discussed with reference to FIG. 12 to FIG. 16 through cross-sectional views taken along lines A-B, C-D, E-F, and G-H in FIG. 11.

FIG. 12 to FIG. 16 are cross-sectional views of four areas (areas indicated by lines A-B, C-D, E-F, and G-H) in the first display area DA1 of the display panel 110 according to embodiments of this specification.

The stacked structures of the insulating layers and metal layers in the cross-sectional views of the display panel 110 in FIG. 12 to FIG. 16 are almost the same as those in the cross-sectional view of FIG. 5. Accordingly, hereinafter, the description of structures identical to those in the cross-sectional view of FIG. 5 may be omitted.

Referring to FIG. 12 to FIG. 16, in the first display area DA1, the electronic device 10 may be disposed below the substrate 111.

Referring to FIG. 12 to FIG. 16, various insulating layers may be disposed on the substrate 111. The various insulating layers may be insulating layers for forming transistors and capacitors included in subpixels SP and for forming various signal lines (e.g., data lines, gate lines, and various power lines).

For example, the various insulating layers may include a first buffer layer 311, a first gate insulating layer 312, a first interlayer insulating layer 313, a second buffer layer 321, a second gate insulating layer 322, a second interlayer insulating layer 323, a first planarization layer 331, a second planarization layer 332, and a bank 340.

For example, the first buffer layer 311 may include a lower buffer layer 311a and an upper buffer layer 311b. The lower buffer layer 311a may include a first lower buffer layer MBUF1 and a second lower buffer layer MBUF2. The first shield pattern BSM1 may be disposed between the first lower buffer layer MBUF1 and the second lower buffer layer MBUF2.

For example, the various insulating layers may further include an encapsulation layer 200. For example, the various insulating layers disposed on the substrate 111 may further include insulating layers for forming a touch sensor, such as a touch buffer layer 351, a touch interlayer insulating layer 352, and a touch protection layer 353.

For example, the various insulating layers may further include an additional insulating layer 1200 disposed on the insulating layers for forming the touch sensor. For example, the additional insulating layer 1200 may be an organic layer or an inorganic layer. As one example, the additional insulating layer 1200 may include the same organic insulating material as the second encapsulation layer 342.

Referring to FIG. 12 to FIG. 16, the various insulating layers may include an organic insulating layer and an inorganic insulating layer.

Referring to FIG. 12 to FIG. 16, various metal layers may be disposed among the various insulating layers on the substrate 111. Through these metal layers, electrodes E1a, E1b, E1c, E2a, E2b, and E2c of the transistors TFT1 and TFT2, and electrodes CAPE1 and CAPE2 of the capacitors Cst may be formed, and various signal lines, such as data lines, gate lines, and various power lines, may be formed.

For example, the various metal layers may include a gate electrode layer in which the gate electrodes E1a and E2a of the transistors TFT1 and TFT2 are formed, a source-drain metal layer in which the source/drain electrodes E1b, E1c, E2b, and E2c of the transistors TFT1 and TFT2 are formed, a shield pattern layer in which the shield pattern BSM1 is formed under the transistors TFT1 and TFT2, a pixel electrode layer in which the pixel electrode PE of the light-emitting device ED is formed, and a common electrode layer in which the common electrode CE of the light-emitting device ED is formed.

For example, the various metal layers may further include a connection electrode layer for forming a connection electrode RE disposed between the source-drain metal layer and the pixel electrode layer.

For example, the source-drain metal layer may include a first source-drain metal layer and a second source-drain metal layer, which are different metal layers.

For example, the various metal layers may further include a first touch metal layer and a second touch metal layer as metal layers for forming a touch sensor.

In addition to the above-mentioned metal layers, the various metal layers disposed on the substrate 111 may further include other additional metal layers.

Referring to FIG. 12 to FIG. 16, among the various insulating layers disposed on the substrate 111, a semiconductor material for forming active layers ACT1 and ACT2 of transistors TFT1 and TFT2 may be disposed between certain insulating layers. For example, the active layers of transistors TFT1 and TFT2 may include a first active layer ACT1 and a second active layer ACT2. The first active layer ACT1 and the second active layer ACT2 may be formed of different semiconductor materials. As one example, the first active layer ACT1 may include amorphous silicon, polysilicon, or low-temperature polysilicon (LTPS), and the second active layer ACT2 may include an oxide semiconductor. As another example, the first active layer ACT1 may include an oxide semiconductor, and the second active layer ACT2 may include amorphous silicon, polysilicon, or low-temperature polysilicon (LTPS).

Referring to FIG. 12 to FIG. 16, an organic layer EL made of an organic material may be further disposed on the substrate 111. The organic layer EL may also be referred to as the intermediate layer EL of the light-emitting devices. As described above, the organic layer EL may include organic material patterns OMP.

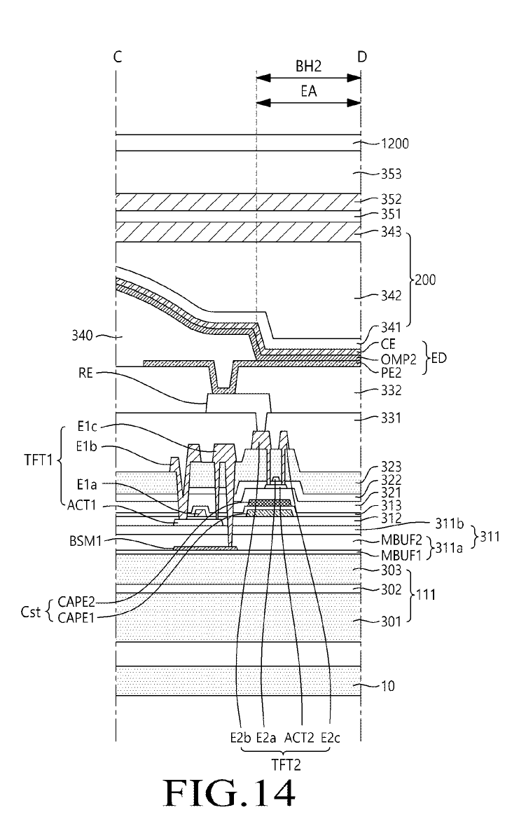

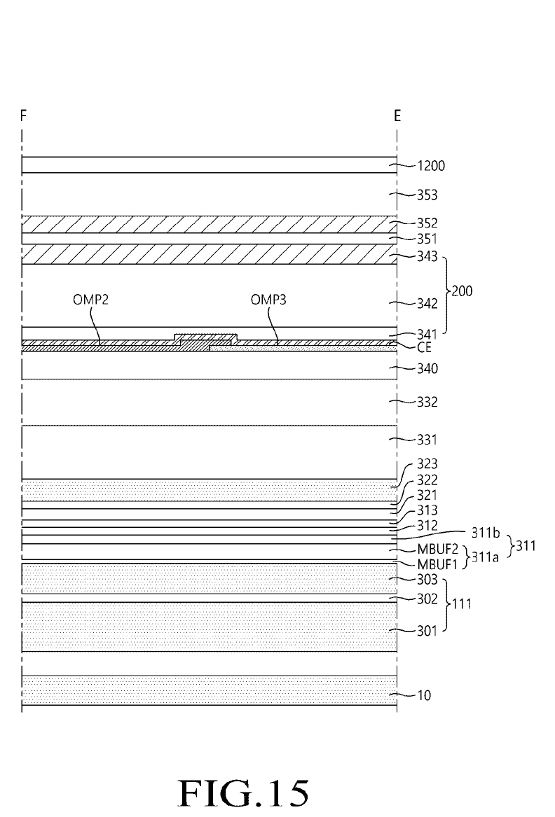

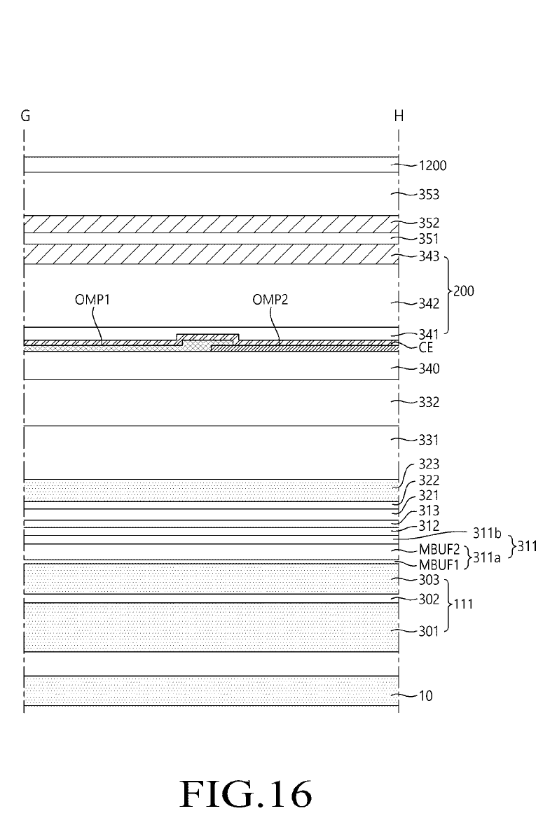

FIG. 12 and FIG. 13 are cross-sectional views taken along line A-B of FIG. 11. FIG. 14 is a cross-sectional view taken along line C-D of FIG. 11. FIG. 15 is a cross-sectional view taken along line E-F of FIG. 11. FIG. 16 is a cross-sectional view taken along line G-H of FIG. 11.

FIGS. 12 and 13 are cross-sectional views taken along line A-B across a single light transmission pattern MPL in a region where the first organic material pattern OMP1, the light transmission pattern MPL, and the third organic material pattern OMP3 are disposed. FIG. 14 is a cross-sectional view taken along line C-D in a region where the second pixel electrode PE2 and the second organic material pattern OMP2 are disposed. FIG. 15 is a cross-sectional view taken along line E-F in a region including the boundary between the second organic material pattern OMP2 and the third organic material pattern OMP3. FIG. 16 is a cross-sectional view taken along line G-H in a region including the boundary between the first organic material pattern OMP1 and the second organic material pattern OMP2.

Referring to FIG. 12 to FIG. 16, the bank 340 may be disposed between the insulating layer and the organic layer EL. Here, the insulating layer refers to the insulating layer disposed between the substrate 111 and the bank 340 among the insulating layers disposed on the substrate 111. For example, the insulating layer may include at least one of the first buffer layer 311, the first gate insulating layer 312, the first interlayer insulating layer 313, the second buffer layer 321, the second gate insulating layer 322, the second interlayer insulating layer 323, the first planarization layer 331, and the second planarization layer 332.

Referring to FIG. 12 to FIG. 14, the bank 340 may include a first bank holes BH1 overlapping with each of a plurality of light transmission patterns MPL, and a second bank hole BH2 overlapping with at least a portion of each of a plurality of pixel electrodes PE.

Referring to FIG. 12 and FIG. 13, each of the plurality of light transmission patterns MPL may be disposed inside a first bank hole BH1 of the bank 340. That is, each of the plurality of light transmission patterns MPL may not overlap with the bank 340. As a result, the bank 340 may not be disposed below the plurality of light transmission patterns MPL.

Referring to FIG. 12 and FIG. 13, the first bank holes BH1 of the bank 340 may each overlap with at least two openings CH formed in the common electrode CE.

Referring to FIG. 14, the second bank holes BH2 of the bank 340 may overlap with the emission areas EA corresponding to the plurality of pixel electrodes PE.

Referring to FIG. 12 and FIG. 13, each of the at least two first organic material patterns OMP1 that do not overlap with the least two first pixel electrodes PE1 may include: a first portion OMP1a disposed on the bank 340, a second portion OMP1b extending from the first portion OMP1a and disposed along the side surface of the bank 340, and a third portion OMP1c extending from the second portion OMP1b and disposed inside the first bank hole BH1.

Referring to FIG. 12 and FIG. 13, each of at least two third organic material patterns OMP3 that do not overlap with at least two third pixel electrodes PE3 may include: a fourth portion OMP3a disposed on the bank 340, a fifth portion OMP3b extending from the fourth portion OMP3a and disposed along the side surface of the bank 340, and a sixth portion OMP3c extending from the fifth portion OMP3b and disposed inside the first bank hole BH1.

Referring to FIG. 12 and FIG. 13, the light transmission pattern MPL disposed inside each first bank hole BH1 may be disposed on the third portions OMP1c of the first organic material patterns OMP1 and the sixth portions OMP3c of each third organic material patterns OMP3.

Referring to FIG. 12 and FIG. 13, the first portions OMP1a and second portions OMP1b of each first organic material pattern OMP1, and the fourth portions OMP3a and fifth portions OMP3b of each third organic material pattern OMP3 may overlap with the common electrode CE. The third portions OMP1c of each first organic material pattern OMP1 and the sixth portions OMP3c of each third organic material pattern OMP3 may overlap with the light transmission pattern MPL.

Referring to FIG. 12, the edge portions of the third portions OMP1c of each first organic material pattern OMP1 and the sixth portions OMP3c of each third organic material pattern OMP3 may overlap with each other in the vertical direction.

Referring to FIG. 12, one of the plurality of second organic material patterns OMP2 may be disposed between the edge portions of the third portions OMP1c of each first organic material pattern OMP1 and the sixth portions OMP3c of each third organic material pattern OMP3.

Referring to FIG. 12, the area where the light transmission pattern MPL is disposed may include a region where the first organic material pattern OMP1, the second organic material pattern OMP2, and the third organic material pattern OMP3 are all vertically overlapped.

Referring to FIG. 13, the edge portions of the third portions OMP1c of each first organic material pattern OMP1 and the sixth portions OMP3c of each third organic material pattern OMP3 may be spaced apart from each other in the horizontal direction. In this case, the edge portions of the third portions OMP1c of each first organic material pattern OMP1 and the sixth portions OMP3c of each third organic material pattern OMP3 may not overlap in the vertical direction.

Referring to FIG. 13, the light transmission pattern MPL may be disposed between the side surfaces of the edge of the third portions OMP1c of each first organic material pattern OMP1 and the sixth portions OMP3c of each third organic material pattern OMP3. That is, the light transmission pattern MPL may be interposed (inserted) between the side surfaces of the edge of the third portions OMP1c of each first organic material pattern OMP1 and the sixth portions OMP3c of each third organic material pattern OMP3.

Referring to FIG. 15 and FIG. 16, the edge portions of two adjacent organic material patterns OMP among the plurality of organic material patterns OMP may overlap in the vertical direction.

According to the example of FIG. 15, in the boundary region E-F between the second organic material pattern OMP2 and the third organic material pattern OMP3, the edge portion of the second organic material pattern OMP2 and the edge portion of the third organic material pattern OMP3 may overlap in the vertical direction. That is, one of the edge portions of the second organic material pattern OMP2 and the third organic material pattern OMP3 may be disposed on top of the other.

According to the example of FIG. 16, in the boundary region (E-F) between the first organic material pattern OMP1 and the second organic material pattern OMP2, the edge portion of the first organic material pattern OMP1 and the edge portion of the second organic material pattern OMP2 may overlap in the vertical direction. That is, one of the edge portions of the first organic material pattern OMP1 and the second organic material pattern OMP2 may be disposed on top of the other.

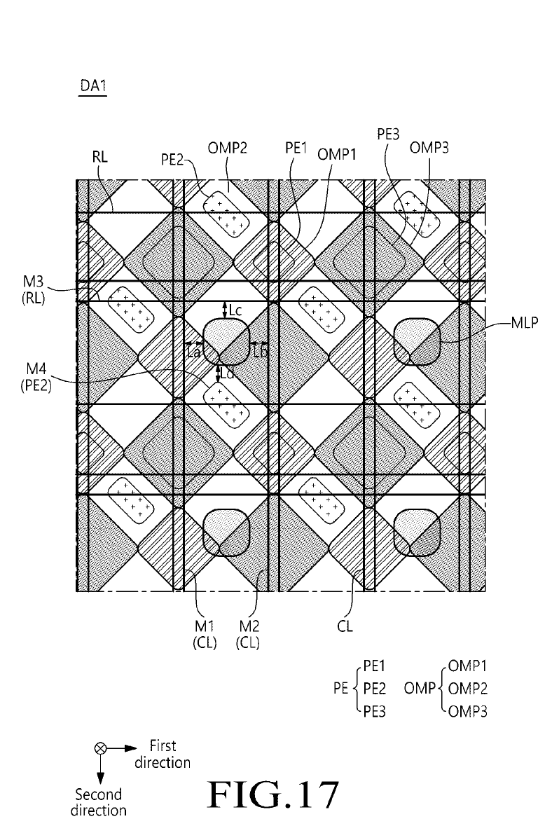

FIG. 17 is a plan view of the first display region DA1 of the display panel 110 according to the embodiments of this specification. FIG. 17 is the same plan view as FIG. 7.

Referring to FIG. 17, the first display area DA1 may include first signal lines RL extending in a first direction and second signal lines CL extending in a second direction different from the first direction. For example, the first signal lines RL may include various gate lines, while the second signal lines CL may include data lines and power supply lines.

The first signal lines RL and the second signal lines CL may be formed using the various metal layers mentioned above.

Referring to FIG. 17, the display panel 110 according to the embodiments of this specification may further include a first metal M1 positioned adjacent to the left side of the first light transmission pattern MPL among two or more light transmission patterns MPL, a second metal M2 positioned adjacent to the right side of the first light transmission pattern MPL, a third metal M3 positioned adjacent to the upper side of the first light transmission pattern MPL, and a fourth metal M4 positioned adjacent to the lower side of the first light transmission pattern MPL.

Referring to FIG. 17, each of the first to fourth metals M1, M2, M3, and M4 may be various signal lines or various electrodes (e.g., pixel electrodes, transistor electrodes, etc.).

For example, according to the example of FIG. 17, each of the first metal M1 and the second metal M2 may be the second signal lines CL, the third metal M3 may be the first signal line RL, and the fourth metal M4 may be the pixel electrode PE2. However, the embodiments described in this specification are not limited thereto.

Referring to FIG. 17, the distance La between the first light transmission pattern MPL and the first metal M1 may correspond to the distance Lb between the first light transmission pattern MPL and the second metal M2. The distance Lc between the first light transmission pattern MPL and the third metal M3 may correspond to the distance Ld between the first light transmission pattern MPL and the fourth metal M4. For example, the distance La between the first light transmission pattern MPL and the first metal M1 may be the same as or have a predetermined allowable difference from the distance Lb between the first light transmission pattern MPL and the second metal M2. Similarly, the distance Lc between the first light transmission pattern MPL and the third metal M3 may be the same as or have a predetermined allowable difference from the distance Ld between the first light transmission pattern MPL and the fourth metal M4.

Due to this distance-related structure, it may be possible to minimize cases where the light transmission pattern MPL overlaps with surrounding metals due to process variations during the manufacturing process of the display panel 110, thereby improving the transmittance of the first display area DA1.

The display device 100 according to the embodiments of this specification may comprise: a substrate 111 comprising a display area DA in which an image is displayed, wherein the display area DA includes a first display area DA1 having a plurality of light-emitting areas and at least one transmissive area, and a second display area DA2 positioned outside the first display area DA1 and including a plurality of light-emitting areas; an insulating layer disposed on the substrate 111; a plurality of pixel electrodes PE disposed on the insulating layer and positioned in each of the plurality of light-emitting areas included in each of the first display area DA1 and the second display area DA2; an intermediate layer EL disposed on the plurality of pixel electrodes PE; a common electrode CE disposed on the intermediate layer EL; a light transmission pattern MPL disposed on the intermediate layer EL and disposed in the first display area DA1; a first metal M1 positioned adjacent to the left side of the light transmission pattern MPL; a second metal M2 positioned adjacent to the right side of the light transmission pattern MPL; a third metal M3 positioned adjacent to the upper side of the light transmission pattern MPL; and a fourth metal M4 positioned adjacent to the lower side of the light transmission pattern MPL.

The common electrode CE may have two or more openings CH positioned in the first display area DA1. Each of the two or more light transmission patterns MPL may be positioned inside each of the two or more openings CH or may be positioned to overlap with each of the two or more openings CH.

The distance La between the first light transmission pattern MPL and the first metal M1 may be the same as the distance Lb between the first light transmission pattern MPL and the second metal M2. The distance Lc between the first light transmission pattern MPL and the third metal M3 may be the same as the distance Ld between the first light transmission pattern MPL and the fourth metal M4.

Each of the first metal M1, second metal M2, third metal M3, and fourth metal M4 may be a signal line or an electrode (e.g., a pixel electrode).

The intermediate layer EL may be an organic layer including a plurality of organic material patterns OMP.

In the first display area DA1, the plurality of organic material patterns OMP may include at least two organic material patterns OMP overlapping with at least two pixel electrodes PE positioned in the first display area DA1 among the plurality of pixel electrodes PE and at least two organic material patterns OMP not overlapping with the at least two pixel electrodes PE.

The light transmission pattern MPL may overlap with at least a portion of at least one organic material pattern OMP among the plurality of organic material patterns OMP that do not overlap with at least two pixel electrodes PE.

For example, the first display area DA1 may include a plurality of unit areas UA, and each of the plurality of unit areas UA may have four organic material patterns OMP among the plurality of organic material patterns OMP but is not limited thereto.

For example, the four organic material patterns OMP may include one first organic material pattern OMP1, two second organic material patterns OMP2, and one third organic material pattern OMP3, but is not limited thereto.

The first organic material pattern OMP1 may include an organic material for emitting first-color light, the second organic material pattern OMP2 may include an organic material for emitting second-color light, and the third organic material pattern OMP3 may include an organic material for emitting third-color light.

Two or more light transmission patterns MPL may be disposed in only some of the plurality of unit areas UA. For example, among the two or more light transmission patterns MPL, the first light transmission pattern MPL may be disposed in the first unit area UA among the plurality of unit areas UA. A part of each of the four organic material patterns OMP disposed in the first unit area UA may overlap with the first light transmission pattern MPL.

The embodiments of this specification described above can be briefly summarized as follows.

The display device according to the embodiments of this specification may comprise: a substrate comprising a display area in which an image is displayed, wherein the display area includes a first display area including a plurality of light-emitting areas and at least one transmissive area, and a second display area positioned outside the first display area and including a plurality of light-emitting areas; an insulating layer disposed on the substrate; a plurality of pixel electrodes disposed on the insulating layer and positioned in each of the plurality of light-emitting areas included in each of the first display area and the second display area; an organic layer disposed on the plurality of pixel electrodes; and a common electrode disposed on the organic layer.

According to the display device of the embodiments of this specification, the organic layer may include a plurality of organic material patterns.

According to the display device of the embodiments of this specification, in the first display area, the plurality of organic material patterns may include at least two organic material patterns overlapping with at least two pixel electrodes disposed in the first display area among the plurality of pixel electrodes, and at least two organic material patterns not overlapping with the at least two pixel electrodes.

According to the display device of the embodiments of this specification, each of the at least two organic material patterns not overlapping with the at least two pixel electrodes may include a light-emitting layer.

The display device according to the embodiments of this specification may further comprise at least two light transmission patterns disposed on the organic layer, spaced apart from each other, and disposed in the first display area.

According to the display device of the embodiments of this specification, the common electrode may have at least two openings positioned in the first display area. Each of the at least two light transmission patterns may be positioned inside each of the at least two openings or may be positioned to overlap with each of the at least two openings.

According to the display device of the embodiments of this specification, at least a portion of at least one of the at least two light transmission patterns may overlap with at least a portion of at least one of the at least two organic material patterns not overlapping with the at least two pixel electrodes.

According to the display device of the embodiments of this specification, in the first display area, the plurality of pixel electrodes may include at least two first pixel electrodes included in at least two first sub-pixels for emitting first-color light, at least two second pixel electrodes included in at least two second sub-pixels for emitting second-color light, and at least two third pixel electrodes included in at least two third sub-pixels for emitting third-color light. Here, the first-color light, second-color light, and third-color light may be different from each other.

According to the display device of the embodiments of this specification, in the first display area, the plurality of organic material patterns may include a plurality of first organic material patterns configured to emit first-color light, a plurality of second organic material patterns configured to emit second-color light, and a plurality of third organic material patterns configured to emit third-color light.

According to the display device of the embodiments of this specification, the plurality of first organic material patterns may be spaced apart from each other. A second organic material pattern or a third organic material pattern may be disposed between two adjacent first organic material patterns among the plurality of first organic material patterns.

According to the display device of the embodiments of this specification, the plurality of third organic material patterns may be spaced apart from each other. A first organic material pattern or a second organic material pattern may be disposed between two adjacent third organic material patterns among the plurality of third organic material patterns.

According to the display device of the embodiments of this specification, the first display area may include a plurality of unit areas. Each of the plurality of unit areas may have four organic material patterns disposed among the plurality of organic material patterns. The four organic material patterns may include one first organic material pattern, two second organic material patterns, and one third organic material pattern.

According to the display device of the embodiments of this specification, at least two light transmission patterns may be disposed only in some of the plurality of unit areas. Among the at least two light transmission patterns, a first light transmission pattern may be disposed in a first unit area among the plurality of unit areas. A part of each of the four organic material patterns disposed in the first unit area may overlap with the first light transmission pattern.

According to the display device of the embodiments of this specification, in the first display area, the plurality of first organic material patterns may include at least two first organic material patterns that overlap with at least two first pixel electrodes, and at least two first organic material patterns that do not overlap with the at least two first pixel electrodes.

According to the display device of the embodiments of this specification, in the first display area, the plurality of third organic material patterns may include at least two third organic material patterns that overlap with at least two third pixel electrodes, and at least two third organic material patterns that do not overlap with the at least two third pixel electrodes.

According to the display device of the embodiments of this specification, at least a portion of each of the at least two light transmission patterns may overlap with at least a portion of at least one of the at least two first organic material patterns that do not overlap with the at least two first pixel electrodes, or at least a portion of at least one of the at least two third organic material patterns that do not overlap with the at least two third pixel electrodes.

According to the display device of the embodiments of this specification, in the first display area, the plurality of second organic material patterns may include at least two second organic material patterns that overlap with at least two second pixel electrodes, and at least two second organic material patterns that do not overlap with the at least two second pixel electrodes. At least a portion of each of the at least two light transmission patterns may overlap with at least a portion of at least one of the at least two second organic material patterns that do not overlap with the at least two second pixel electrodes.

The display device according to the embodiments of this specification may further comprise a bank disposed between the insulating layer and the organic layer. The bank may include a first bank hole that overlaps with each of the plurality of light transmission patterns and a second bank hole that overlaps with at least a portion of each of the plurality of pixel electrodes.

According to the display device of the embodiments of this specification, each of the at least two first organic material patterns that do not overlap with the at least two first pixel electrodes may include: a first portion disposed on the bank; a second portion extending from the first portion and disposed along a side surface of the bank; and a third portion extending from the second portion and disposed in the first bank hole. Each of the at least two third organic material patterns that do not overlap with the at least two third pixel electrodes may include: a fourth portion disposed on the bank; a fifth portion extending from the fourth portion and disposed along a side surface of the bank; and a sixth portion extending from the fifth portion and disposed in the first bank hole.

According to the display device of the embodiments of this specification, a light transmission pattern disposed in the first bank hole may be disposed on the third portion and the sixth portion.

According to the display device of the embodiments of this specification, the first portion, the second portion, the fourth portion, and the fifth portion may overlap with the common electrode, and the third portion and the sixth portion may overlap with the light transmission pattern.

According to the display device of the embodiments of this specification, an edge of the third portion and an edge of the sixth portion may vertically overlap with each other, and one of the plurality of second organic material patterns may be disposed between the edge of the third portion and the edge of the sixth portion.

According to the display device of the embodiments of this specification, an edge of the third portion and an edge of the sixth portion may be horizontally spaced apart from each other, and the light transmission pattern may be disposed between the side surface of the edge of the third portion and the side surface of the edge of the sixth portion.

According to the display device of the embodiments of this specification, at the boundary region between two adjacent organic material patterns among the plurality of organic material patterns, an edge of each of the two organic material patterns may vertically overlap with each other.

The display device according to the embodiments of this specification may further comprise a first metal positioned adjacent to the left side of a first light transmission pattern among two or more light transmission patterns, a second metal positioned adjacent to the right side of the first light transmission pattern, a third metal positioned adjacent to the upper side of the first light transmission pattern, and a fourth metal positioned adjacent to the lower side of the first light transmission pattern.

According to the display device of the embodiments of this specification, the distance between the first light transmission pattern and the first metal may correspond to the distance between the first light transmission pattern and the second metal, and the distance between the first light transmission pattern and the third metal may correspond to the distance between the first light transmission pattern and the fourth metal.

According to the display device of the embodiments of this specification, each of the first metal, the second metal, the third metal, and the fourth metal may be a signal line or a pixel electrode.

According to the display device of the embodiments of this specification, two or more light transmission patterns may include an organic material.

The display device according to the embodiments of this specification may further comprise an electronic device positioned below the substrate, overlapping the first display area, and receiving light passing through the first display area.

The display device according to the embodiments of this specification may further comprise an encapsulation layer disposed on the common electrode, and a plurality of touch electrodes disposed on the encapsulation layer.

According to the display device of the embodiments of this specification, the first display area may include a first optical area and a second optical area. The first optical area and the second optical area may differ in at least one of light transmittance, resolution, the number of sub-pixels per unit area, and sub-pixel size.

According to the display device of the embodiments of this specification, the plurality of touch electrodes may be disposed in one of the first optical area and the second optical area, and may not be disposed in the other.

According to the embodiments of this specification, the display device comprises: a substrate including a display area in which an image is displayed, wherein the display area comprises a first display area including a plurality of light-emitting areas and at least one transmissive area, and a second display area positioned outside the first display area and including a plurality of light-emitting areas; an insulating layer disposed on the substrate; a plurality of pixel electrodes disposed on the insulating layer and positioned in each of the plurality of light-emitting areas included in each of the first display area and the second display area; an intermediate layer disposed on the plurality of pixel electrodes; a common electrode disposed on the intermediate layer; a light transmission pattern disposed on the intermediate layer and positioned in the first display area; a first metal positioned adjacent to the left side of the light transmission pattern; a second metal positioned adjacent to the right side of the light transmission pattern; a third metal positioned adjacent to the upper side of the light transmission pattern; and a fourth metal positioned adjacent to the lower side of the light transmission pattern.

According to the display device of the embodiments of this specification, the common electrode includes at least two openings positioned in the first display area. Each of the at least two light transmission patterns is positioned inside a respective one of the at least two openings or overlaps with a respective one of the at least two openings.

According to the display device of the embodiments of this specification, a distance between the light transmission pattern and the first metal corresponds to a distance between the light transmission pattern and the second metal. A distance between the light transmission pattern and the third metal corresponds to a distance between the light transmission pattern and the fourth metal.

According to the display device of the embodiments of this specification, each of the first metal, the second metal, the third metal, and the fourth metal may be a signal line or a pixel electrode.

According to the display device of the embodiments of this specification, the intermediate layer may comprise a plurality of organic material patterns.

According to the display device of the embodiments of this specification, in the first display area, the plurality of organic material patterns may comprise: at least two organic material patterns that overlap with at least two pixel electrodes positioned in the first display area among the plurality of pixel electrodes; and at least two organic material patterns that do not overlap with the at least two pixel electrodes positioned in the first display area.

According to the display device of the embodiments of this specification, the light transmission pattern may overlap with at least a portion of at least one organic material pattern among the plurality of organic material patterns that does not overlap with at least two pixel electrodes.

According to the display device of the embodiments of this specification, each of the at least two organic material patterns that do not overlap with the at least two pixel electrodes may comprise an emission layer.

According to the embodiments of this specification, a display device having a light transmission structure may be provided, enabling an electronic device that requires light reception from the front to receive light (e.g., visible light, infrared light, or ultraviolet light) properly without being exposed on the front.

According to the embodiments of this specification, despite structural differences between a transmissive area, which requires high light transmittance, and a non-transmissive area, which may allow low light transmittance or no light transmission (i.e., the presence or absence of a light transmission structure), the organic layer for the light-emitting devices may be uniformly patterned into a plurality of organic material patterns in both the transmissive and non-transmissive areas. This may simplify the process, enhance efficiency, and optimize manufacturing in the display device.

According to the embodiments of this specification, a display device having high light transmittance in an area overlapping an electronic device that requires light reception may be provided.

According to the embodiments of this specification, a display device having excellent resolution in an area overlapping an electronic device that requires light reception may be provided.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area in which an image is displayed, wherein the display area comprises a first display area including a plurality of light-emitting areas and at least one transmissive area, and a second display area positioned outside the first display area and including a plurality of light-emitting areas;
an insulating layer on the substrate;
a plurality of pixel electrodes on the insulating layer and positioned in each of the plurality of light-emitting areas included in each of the first display area and the second display area;
an organic layer on the plurality of pixel electrodes; and
a common electrode on the organic layer,
wherein, in the first display area and the second display area, the organic layer comprises a plurality of organic material patterns,
wherein, in the first display area, the plurality of organic material patterns comprise:
at least two organic material patterns overlapping with at least two of the pixel electrodes disposed in the first display area, among the plurality of pixel electrodes; and
at least two organic material patterns not overlapping with the at least two pixel electrodes.

2. The display device according to claim 1, wherein each of the plurality of organic material patterns that do not overlap the at least two pixel electrodes comprises an emission layer.

3. The display device according to claim 1, further comprising at least two light-transmissive patterns on the organic layer, spaced apart from each other and disposed in the first display area,
wherein the common electrode has at least two openings positioned in the first display area, and
wherein each of the at least two light-transmissive patterns is positioned either inside each of the at least two openings or to overlap with each of the at least two openings.

4. The display device according to claim 3, wherein at least a portion of at least one of the at least two light-transmissive patterns overlaps with at least a portion of the at least two organic material patterns that do not overlap the at least two pixel electrodes.

5. The display device according to claim 3, wherein, in the first display area, the plurality of pixel electrodes comprises:
at least two first pixel electrodes included in at least two first sub-pixels for emitting a first color light;
at least two second pixel electrodes included in at least two second sub-pixels for emitting a second color light; and
at least two third pixel electrodes included in at least two third sub-pixels for emitting a third color light,
wherein the first color light, the second color light, and the third color light are different from each other,
wherein, in the first display area, the plurality of organic material patterns comprise:
a plurality of first organic material patterns configured to emit the first color light;
a plurality of second organic material patterns configured to emit the second color light; and
a plurality of third organic material patterns configured to emit the third color light,
wherein the plurality of first organic material patterns are spaced apart from each other,
wherein a second organic material pattern or a third organic material pattern is disposed between two adjacent first organic material patterns among the plurality of first organic material patterns,
wherein the plurality of third organic material patterns are spaced apart from each other, and
wherein a first organic material pattern or a second organic material pattern is disposed between two adjacent third organic material patterns among the plurality of third organic material patterns.

6. The display device according to claim 5, wherein the first display area comprises a plurality of unit areas,
wherein four organic material patterns among the plurality of organic material patterns is disposed in each of the plurality of unit areas, and
wherein the four organic material patterns comprise one first organic material pattern, two second organic material patterns, and one third organic material pattern.

7. The display device according to claim 6,
wherein the at least two light-transmissive patterns are disposed only in some of the plurality of unit areas,
wherein a first light-transmissive pattern among the at least two light-transmissive patterns is disposed in a first unit area among the plurality of unit areas, and
wherein at least a portion of each of the four organic material patterns disposed in the first unit area overlaps with the first light-transmissive pattern.

8. The display device according to claim 5, wherein, in the first display area, the plurality of first organic material patterns comprises:
at least two first organic material patterns each overlapping with a respective one of the at least two first pixel electrodes; and
at least two first organic material patterns not overlapping with the at least two first pixel electrodes,
wherein, in the first display area, the plurality of third organic material patterns comprise:
at least two third organic material patterns each overlapping with a respective one of the at least two third pixel electrodes; and
at least two third organic material patterns not overlapping with the at least two third pixel electrodes.

9. The display device according to claim 8, wherein at least a portion of each of the at least two light-transmissive patterns overlaps with at least a portion of at least one of the at least two first organic material patterns that do not overlap the at least two first pixel electrodes or at least a portion of at least one of the at least two third organic material patterns that do not overlap the at least two third pixel electrodes.

10. The display device according to claim 8, wherein, in the first display area, the plurality of second organic material patterns comprises:
at least two second organic material patterns each overlapping with a respective one of the at least two second pixel electrodes; and
at least two second organic material patterns not overlapping with the at least two second pixel electrodes,
wherein at least a portion of each of the at least two light-transmissive patterns overlaps with at least a portion of at least one of the at least two second organic material patterns that do not overlap the at least two second pixel electrodes.

11. The display device according to claim 8, further comprising a bank between the insulating layer and the organic layer, wherein the bank comprises:
first bank holes each overlapping with a respective one of the plurality of light-transmissive patterns; and
second bank holes each overlapping with at least a portion of a respective one of the plurality of pixel electrodes.

12. The display device according to claim 11, wherein each of the plurality of first organic material patterns that do not overlap the at least two first pixel electrodes comprises:
a first portion on the bank;
a second portion extending from the first portion and disposed along a side surface of the bank; and
a third portion extending from the second portion and disposed in the first bank hole,
wherein each of the plurality of third organic material patterns that do not overlap the at least two third pixel electrodes comprises:
a fourth portion on the bank;
a fifth portion extending from the fourth portion and disposed along a side surface of the bank; and
a sixth portion extending from the fifth portion and disposed in the first bank hole,
wherein the light-transmissive pattern disposed in the first bank hole is positioned on the third portion and the sixth portion.

13. The display device according to claim 12, wherein the first portion, the second portion, the fourth portion, and the fifth portion overlap with the common electrode, and the third portion and the sixth portion overlap with the light-transmissive pattern.

14. The display device according to claim 12, wherein the edge of the third portion and the edge of the sixth portion overlap in a vertical direction, and one of the plurality of second organic material patterns is disposed between the edge of the third portion and the edge of the sixth portion.

15. The display device according to claim 12, wherein the edge of the third portion and the edge of the sixth portion are spaced apart in a horizontal direction, and the light-transmissive pattern is disposed between the side surfaces of the edge of the third portion and the edge of the sixth portion.

16. The display device according to claim 5, wherein, in the boundary area between two adjacent organic material patterns among the plurality of organic material patterns, the edge of each of the two organic material patterns overlaps in a vertical direction.

17. The display device according to claim 3, further comprising:
a first metal adjacent to the left side of a first light-transmissive pattern among the at least two light-transmissive patterns;
a second metal adjacent to the right side of the first light-transmissive pattern;
a third metal adjacent to the top of the first light-transmissive pattern; and
a fourth metal adjacent to the bottom of the first light-transmissive pattern,
wherein each of the first metal, the second metal, the third metal, and the fourth metal is a signal line or a pixel electrode,
wherein the distance between the first light-transmissive pattern and the first metal corresponds to the distance between the first light-transmissive pattern and the second metal, and
wherein the distance between the first light-transmissive pattern and the third metal corresponds to the distance between the first light-transmissive pattern and the fourth metal.

18. The display device according to claim 3, wherein the at least two light-transmissive patterns comprise an organic material.

19. A display device comprising:
a substrate including a display area in which an image is displayed, wherein the display area comprises a first display area including a plurality of light-emitting areas and at least one transmissive area and a second display area positioned outside the first display area and including a plurality of light-emitting areas;
an insulating layer on the substrate;
a plurality of pixel electrodes on the insulating layer and positioned in each of the plurality of light-emitting areas included in each of the first display area and the second display area;
an intermediate layer on the plurality of pixel electrodes;
a common electrode on the intermediate layer;
a light-transmissive pattern on the intermediate layer and disposed in the first display area;
a first metal adjacent to the left side of the light-transmissive pattern;
a second metal adjacent to the right side of the light-transmissive pattern;
a third metal adjacent to the top of the light-transmissive pattern; and
a fourth metal adjacent to the bottom of the light-transmissive pattern,
wherein the common electrode has at least two openings positioned in the first display area,
wherein each of the at least two light-transmissive patterns is positioned either inside each of the at least two openings or to overlap with each of the at least two openings,
wherein the distance between the light-transmissive pattern and the first metal corresponds to the distance between the light-transmissive pattern and the second metal, and
wherein the distance between the light-transmissive pattern and the third metal corresponds to the distance between the light-transmissive pattern and the fourth metal.

20. The display device according to claim 19, wherein, in the first display area and the second display area, the intermediate layer comprises a plurality of organic material patterns,
wherein, in the first display area, the plurality of organic material patterns comprise:
at least two organic material patterns overlapping with at least two pixel electrodes disposed in the first display area, among the plurality of pixel electrodes; and
at least two organic material patterns not overlapping with the at least two pixel electrodes.
